(19) United States
(12) Patent Application Publication
(10) Pub. No.: US 2023/0209875 A1
(43) Pub. Date: Jun. 29, 2023

(54) LIGHT-EMITTING APPARATUS

(71) Applicant: JOLED INC., TOKYO (JP)

(72) Inventors: Toshihiro FUKUDA, Tokyo (JP); Hiroyoshi Takezawa, Tokyo (JP); Yuki Kishi, Tokyo (JP)

(21) Appl. No.: 18/146,553

(22) Filed: Dec. 27, 2022

(30) Foreign Application Priority Data
Dec. 27, 2021 (JP) 2021-211958

(51) Int. Cl. H10K 50/856; H10K 59/35; H10K 50/852

(52) U.S. Cl. CPC H01L 51/5271; H01L 27/3211; H01L 51/5265; H01L 27/3244

(57) ABSTRACT

A light-emitting apparatus includes a plurality of organic electroluminescent sections, a light extraction surface, and a laminate section. The second reflective layer includes, from the organic light-emitting layer side, a first metal layer, a transparent layer, and a second metal layer thinner than the first metal layer, in this order, and, in each of the organic electroluminescent sections, an interference structure is formed according to a structure that includes a reflection interface A on the organic light-emitting layer side of the first reflective layer, a reflection interface B on the organic light-emitting layer side of the first metal layer, a reflection interface C on the light extraction surface side of the first metal layer, a reflection interface D on the organic light-emitting layer side of the second metal layer, and one or more reflection interfaces E formed according to differences in refractive indexes within the laminate section.

### BACKGROUND

The present disclosure pertains to a light-emitting apparatus using an organic electroluminescent section that emits light according to the phenomenon of organic electroluminescence (EL: Electro Luminescence).

In recent years, many proposals have been made regarding the structure of a light-emitting apparatus that uses an organic EL element (for example, PCT Patent Publication No. WO01/039554, Japanese Patent Laid-open No. 2006-244713, Japanese Patent Laid-open No. 2011-159431, and Japanese Patent Laid-open No. 2011-159433).

### SUMMARY

In such a light-emitting apparatus, with a top emission method, it is not easy to establish both power supply performance and a viewing angle characteristic for chromaticity in conjunction with an increase in size. Accordingly, it is desirable to provide a light-emitting apparatus that can establish both power supply performance and a viewing angle characteristic for chromaticity.

A light-emitting apparatus according to a first aspect of the present disclosure is provided with a plurality of organic electroluminescent sections that each include a first reflective layer, an organic light-emitting layer, and a second reflective layer, and a light extraction surface from which light emitted from each of the organic electroluminescent sections via the second reflective layer is extracted. This light-emitting apparatus is further provided with a laminate section that includes a plurality of types of transparent material layers different from a metal reflective film and is provided between each of the organic electroluminescent sections and the light extraction surface. The second reflective layer includes, from the organic light-emitting layer side, a first metal layer, a transparent layer, and a second metal layer thinner than the first metal layer, in this order. In each of the organic electroluminescent sections, an interference structure is formed according to a structure that includes a reflection interface A on the organic light-emitting layer side of the first reflective layer, a reflection interface B on the organic light-emitting layer side of the first metal layer, a reflection interface C on the light extraction surface side of the first metal layer, a reflection interface D on the organic light-emitting layer side of the second metal layer, and one or more reflection interfaces E formed according to differences in refractive indexes within the laminate section.

In the light-emitting apparatus according to the first aspect of the present disclosure, each of the organic electroluminescent sections is configured by including, from the organic light-emitting layer side, a first metal layer, a transparent layer, and a second metal layer thinner than the first metal layer, in this order. In each of the organic electroluminescent sections, an interference structure is formed according to a structure that includes a reflection interface A on the organic light-emitting layer side of the first reflective layer, a reflection interface B on the organic light-emitting layer side of the first metal layer, a reflection interface C on the light extraction surface side of the first metal layer, a reflection interface D on the organic light-emitting layer side of the second metal layer, and one or more reflection interfaces E formed according to differences in refractive indexes within the laminate section. As a result, it is possible to reduce deterioration of a viewing angle characteristic for chromaticity even in a case where the first metal layer is made to be a thick film.

A light-emitting apparatus according to a second aspect of the present disclosure is provided with a plurality of organic electroluminescent sections that each include a first reflective layer, an organic light-emitting layer, and a second reflective layer, and a light extraction surface from which light emitted from each of the organic electroluminescent sections via the second reflective layer is extracted. The second reflective layer includes, from the organic light-emitting layer side, a first metal layer, a first transparent layer, a second metal layer thinner than the first metal layer, a second transparent layer, and a third metal layer thinner than the first metal layer, in this order. In each of the organic electroluminescent sections, an interference structure is formed according to a structure that includes a reflection interface A on the organic light-emitting layer side of the first reflective layer, a reflection interface B on the organic light-emitting layer side of the first metal layer, a reflection interface C on the light extraction surface side of the first metal layer, a reflection interface D on the organic light-emitting layer side of the second metal layer, and a reflection interface E on the organic light-emitting layer side of the third metal layer.

In the light-emitting apparatus according to the second aspect of the present disclosure, each of the organic electroluminescent sections is configured by including, from the organic light-emitting layer side, a first metal layer, a first transparent layer, a second metal layer thinner than the first metal layer, a second transparent layer, and a third metal layer thinner than the first metal layer, in this order. In each of the organic electroluminescent sections, an interference structure is formed according to a structure that includes a reflection interface A on the organic light-emitting layer side of the first reflective layer, a reflection interface B on the organic light-emitting layer side of the first metal layer, a reflection interface C on the light extraction surface side of the first metal layer, a reflection interface D on the organic light-emitting layer side of the second metal layer, and a reflection interface E on the organic light-emitting layer side of the third metal layer. As a result, it is possible to reduce deterioration of a viewing angle characteristic for chromaticity even in a case where the first metal layer is made to be a thick film.

By virtue of the light-emitting apparatus according to the first aspect and the second aspect of the present disclosure, even in a case where the first metal layer is made to be a thick film, it is possible to reduce deterioration of a viewing angle characteristic for chromaticity, and thus it is possible to establish both power supply performance and a viewing angle characteristic for chromaticity. Note that effects described herein are not necessarily limited to any kind, and any effect from those described in the present disclosure may be achieved.

### BRIEF DESCRIPTION OF THE DRAWINGS

FIG. 1 is a cross-sectional view that represents an approximate configuration of a light-emitting apparatus according to one embodiment of the present disclosure;

FIG. 2 is a cross-sectional view representing a configuration of a red-light-emitting section illustrated in FIG. 1;

FIG. 3 is a cross-sectional view representing a configuration of a green-light-emitting section illustrated in FIG. 1;

FIG. 4 is a cross-sectional view representing a configuration of a blue-light-emitting section illustrated in FIG. 1;

FIG. 5 is a cross-sectional view for giving a description regarding optical action by the light-emitting apparatus illustrated in FIG. 1;

FIG. 6 is a view that represents examples of change in chromaticity due to viewing angles for light-emitting apparatuses according to comparative examples.

FIG. 7 is a view that represents examples of change in luminance due to viewing angles for light-emitting apparatuses according to comparative examples;

FIG. 8 is a view that represents examples of change in chromaticity due to viewing angles for light-emitting apparatuses according to comparative examples as well as examples;

FIG. 9 is a cross-sectional view representing a variation of the configuration of the light-emitting section illustrated in FIG. 1;

FIG. 10 is a cross-sectional view representing a variation of the configuration of the light-emitting section illustrated in FIG. 1;

FIG. 11 is a view represent an approximate configuration of a display apparatus to which the light-emitting apparatus illustrated in FIG. 1 etc., has been applied;

FIG. 12 is a circuit diagram representing a circuit configuration of a pixel illustrated in FIG. 11;

FIG. 13 is a view that represents an example of the appearance of electronic equipment to which the display apparatus illustrated in FIG. 11 has been applied; and

FIG. 14 is a view that represents an example of the appearance of an illumination apparatus to which the light-emitting apparatus illustrated in FIG. 1 etc. has been applied.

### DETAILED DESCRIPTION OF THE PREFERRED EMBODIMENT

With reference to the drawings, description is given in detail in the following order regarding an embodiment of the present disclosure.
1. Embodiment (light-emitting apparatus)
2. Variations (Light-emitting apparatus)
3. Application examples (display apparatus, electronic equipment, illumination apparatus)

### 1. Embodiment

### Configuration

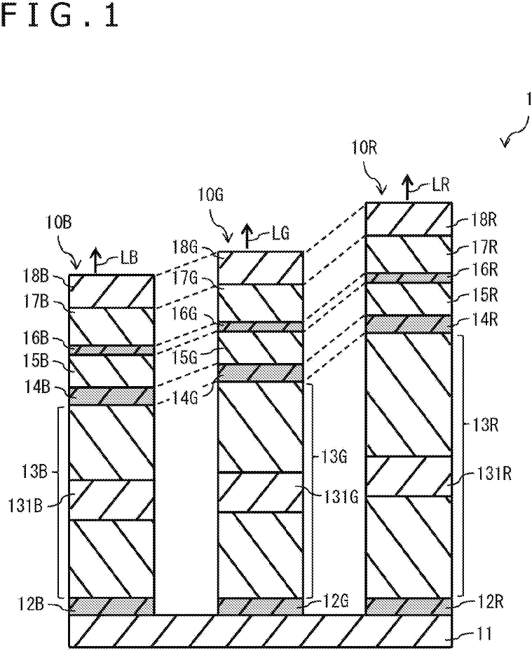

FIG. 1 represents a cross-sectional configuration example of a main part of a light-emitting apparatus 1 according to one embodiment of the present disclosure. The light-emitting apparatus 1 is provided with a substrate 11, and a plurality of red-light-emitting sections 10R, a plurality of green-light-emitting sections 10G, and a plurality of blue-light-emitting sections 10B are provided on the substrate 11. Each red-light-emitting section 10R corresponds to one concrete example of an “organic electroluminescent section” and a “first organic electroluminescent section” according to an embodiment of the present disclosure. Each green-light-emitting section 10G corresponds to one concrete example of an “organic electroluminescent section” and a “first organic electroluminescent section” according to the embodiment of the present disclosure. Each blue-light-emitting section 10B corresponds to one concrete example of an “organic electroluminescent section” and a “second organic electroluminescent section” according to the embodiment of the present disclosure.

Each red-light-emitting section 10R has, on the substrate 11, an electrode layer 12R, a red organic layer 13R that includes a red-light-emitting layer 131R, a metal layer 14R, a transparent layer 15R, a metal layer 16R, a transparent layer 17R, and a transparent layer 18R, in this order. The green-light-emitting section 10G has, on the substrate 11, an electrode layer 12G, a green organic layer 13G that includes a green-light-emitting layer 131G, a metal layer 14G, a transparent layer 15G, a metal layer 16G, a transparent layer 17G, and a transparent layer 18G, in this order. The blue-light-emitting section 10B has, on the substrate 11, an electrode layer 12B, a blue organic layer 13B that includes a blue-light-emitting layer 131B, a metal layer 14B, a transparent layer 15B, a metal layer 16B, a transparent layer 17B, and a transparent layer 18B, in this order. “Transparent” in the present specification indicates having optical transparency in relation to light (in other words, light in the visible region) emitted from the red-light-emitting section 10R, the green-light-emitting section 10G, and the blue-light-emitting section 10B.

The electrode layers 12R, 12G, and 12B correspond to concrete examples of a “first reflective layer” according to the embodiment of the present disclosure. A laminate including the metal layer 14R, the transparent layer 15R, the metal layer 16R, the transparent layer 17R, and the transparent layer 18R corresponds to one concrete example of a “laminate section that includes a plurality of types of transparent material layers different from a metal reflective film” according to the embodiment of the present disclosure. A laminate including the metal layer 14G, the transparent layer 15G, the metal layer 16G, the transparent layer 17G, and the transparent layer 18G corresponds to one concrete example of a “laminate section that includes a plurality of types of transparent material layers different from a metal reflective film” according to the embodiment of the present disclosure. A laminate including the metal layer 14B, the transparent layer 15B, the metal layer 16B, the transparent layer 17B, and the transparent layer 18B corresponds to one concrete example of a “laminate section that includes a plurality of types of transparent material layers different from a metal reflective film” according to the embodiment of the present disclosure.

The red-light-emitting section 10R emits, from a transparent layer 18R side, light in the red wavelength range (red light LR) generated by the red-light-emitting layer 131R due to current injection by the electrode layer 12R and the metal layer 14R. The green-light-emitting section 10G emits, from a transparent layer 18G side, light in the green wavelength range (green light LG) generated by the green-light-emitting layer 131G due to current injection by the electrode layer 12G and the metal layer 14G. The blue-light-emitting section 10B emits, from a transparent layer 18B side, light in the blue wavelength range (blue light LB) generated by the blue-light-emitting layer 131B due to current injection by the electrode layer 12B and the metal layer 14B. The light-emitting apparatus 1 is configured to cause light emitted from the red-light-emitting layer 131R, the green-light-emitting layer 131G, and the blue-light-emitting layer 131B to be multiply reflected between the electrode layers 12R, 12G, and 12B and the transparent layers 18R, 18G, and 18B and light to be extracted from the transparent layers 18R, 18G, and 18B side. In other words, the light-emitting apparatus 1 is a top-surface light-emission type light-emitting apparatus that has a resonator structure.

The substrate 11 is a plate-shaped member for supporting the red-light-emitting layer 131R, the green-light-emitting layer 131G, and the blue-light-emitting layer 131B, and, for example, is configured by a transparent glass substrate or a semiconductor substrate. The substrate 11 may be configured by a flexible substrate. The substrate 11 may be a circuit substrate on which a circuit (later-described pixel circuit 18-1) is provided for driving the red-light-emitting layer 131R, the green-light-emitting layer 131G, and the blue-light-emitting layer 131B.

The electrode layers 12R, 12G, and 12B (first electrodes) are anode electrodes that also function as reflective layers. The electrode layers 12R, 12G, and 12B (first electrodes) are formed using a light reflective material, for example. For example, aluminum (Al), an aluminum alloy, platinum (Pt), gold (Au), chromium (Cr), tungsten (W), or other materials may be given as a light reflective material that can be used for the electrode layers 12R, 12G, and 12B. The electrode layers 12R, 12G, and 12B (first electrodes) may be configured by laminating a transparent electrically conductive material and a light reflective material, for example. The electrode layers 12R, 12G, and 12B may have a lamination structure resulting from laminating silver (Ag) or an Ag alloy with a transparent electrically conductive material such as indium tin oxide (ITO), for example. The thickness of the electrode layers 12R, 12G, and 12B is greater than or equal to 100 nm but less than or equal to 300 nm, for example.

For example, the red organic layer 13R has, from a position close to the electrode layer 12R, a hole injection layer, a hole transport layer, the red-light-emitting layer 131R, an electron transport layer, and an electron injection layer, in this order. For example, the green organic layer 13G has, from a position close to the electrode layer 12G, a hole injection layer, a hole transport layer, the green-light-emitting layer 131G, an electron transport layer, and an electron injection layer, in this order. For example, the blue organic layer 13B has, from a position close to the electrode layer 12B, a hole injection layer, a hole transport layer, the blue-light-emitting layer 131B, an electron transport layer, and an electron injection layer, in this order.

A hole injection layer is for preventing leaks. For example, a hole injection layer is formed using hexaazatriphenylene (HAT) etc. The thickness of a hole injection layer is greater than or equal to 1 nm but less than or equal to 20 nm, for example. A hole transport layer is formed using α-NPD [N, N′-di(1-naphthyl)-N, N′-diphenyl-[1,1′-biphenyl]-4,4′-diamine], for example. The thickness of a hole transport layer is greater than or equal to 15 nm but less than or equal to 100 nm, for example.

The red-light-emitting layer 131R, the green-light-emitting layer 131G, and the blue-light-emitting layer 131B are each configured to emit light of a predetermined color according to holes and electrons combining. The thickness of the red-light-emitting layer 131R, the green-light-emitting layer 131G, and the blue-light-emitting layer 131B is greater than or equal to 5 nm but less than or equal to 150 nm, for example. The red-light-emitting layer 131R emits light of a red wavelength range (first wavelength band). The red-light-emitting layer 131R is formed using rubrene doped with a pyrromethene boron complex, for example. In this point, rubrene is used as a host material. The green-light-emitting layer 131G emits light in a green wavelength range. The green-light-emitting layer 131G is formed using Alq³ (a tris-quinolinol aluminum complex), for example. The blue-light-emitting layer 131B emits light in a blue wavelength range (a second wavelength band having shorter wavelengths than the first wavelength band) having shorter wavelengths than the red wavelength range. The blue-light-emitting layer 131B is formed using ADN (9,10-di(2-naphthyl)anthracene) doped with a diaminochrysene derivative, for example. In this point, ADN is used as a host material, and is a deposited film having a thickness of 20 nm, for example. The diaminochrysene derivative is used as a dopant material, and doped to 5% in a relative thickness ratio, for example.

Each electron transport layer is formed using BCP (2,9-dimethyl-4,7-diphenyl-1,10-phenanthroline). The thickness of the electron transport layer is greater than or equal to 15 nm but less than or equal to 200 nm, for example. Each electron injection layer is formed using lithium fluoride (LiF), for example. The thickness of the electron injection layer is greater than or equal to 0.3 nm but less than or equal to 10 nm, for example.

In the present embodiment, the metal layer 14R, the transparent layer 15R, and the metal layer 16R are electrically connected to each other. A laminate (a second electrode) that includes the metal layer 14R, the transparent layer 15R, and the metal layer 16R is a cathode electrode that forms a pair with the electrode layer 12R, and also functions as a reflective layer. Similarly, the metal layer 14G, the transparent layer 15G, and the metal layer 16G are electrically connected to each other. A laminate (a second electrode) that includes the metal layer 14G, the transparent layer 15G, and the metal layer 16G is a cathode electrode that forms a pair with the electrode layer 12G, and also functions as a reflective layer. The metal layer 14B, the transparent layer 15B, and the metal layer 16B are electrically connected to each other. A laminate (a second electrode) that includes the metal layer 14B, the transparent layer 15B, and the metal layer 16B is a cathode electrode that forms a pair with the electrode layer 12B, and also functions as a reflective layer.

The metal layers 14R, 14G, and 14B are formed using a metal material that has a high reflectance. The metal layers 14R, 14G, and 14B are, for example, formed using magnesium (Mg), silver (Ag), or an alloy of these. The metal layers 14R, 14G, and 14B are thicker than the metal layers 16R, 16G, and 16B. The thickness of the metal layers 14R, 14G, and 14B is greater than or equal to 5 nm but less than or equal to 50 nm, for example. The metal layers 14R, 14G, and 14B are formed by such a metal material that has a high reflectance, whereby it is possible to increase an effect of the resonator structure and improve light extraction efficiency. As a result, it is possible to constrain power consumption and extend the lives of the red-light-emitting section 10R, the green-light-emitting section 10G, and the blue-light-emitting section 10B.

The transparent layers 15R, 15G, and 15B are formed using a transparent electrical conductor material. As the transparent electrical conductor material used for the transparent layers 15R, 15G, and 15B, for example, ITO, indium zinc oxide (IZO), or other materials may be given. The thickness of the transparent layers 15R, 15G, and 15B is greater than or equal to 30 nm but less than or equal to 600 nm, for example. The transparent layer 15R is in contact with the metal layers 14R and 16R. The transparent layer 15G is in contact with the metal layers 14G and 16G. The transparent layer 15B is in contact with the metal layers 14B and 16B.

The metal layers 16R, 16G, and 16B are formed using a metal material that has a high reflectance. For example, magnesium (Mg), silver (Ag), an alloy of these, or other materials may be given as a metal material used for the metal layers 16R, 16G, and 16B. The total thickness of the metal layers 14R, 14G, and 14B and the metal layers 16R, 16G, and 16B is greater than or equal to 38 nm, for example. The metal layers 16R, 16G, and 16B have a thickness of, for example, greater than or equal to 5 nm but less than or equal to 20 nm, which enables the interface on the light source side of the metal layers 16R, 16G, and 16B to be viewed as substantially the same as the interface on the light extraction side of the metal layers 16R, 16G, and 16B, in a later-described interference structure. The metal layer 16R is electrically connected to the metal layer 14R via the transparent layer 15R. The metal layer 16G is electrically connected to the metal layer 14G via the transparent layer 15G. The metal layer 16B is electrically connected to the metal layer 14B via the transparent layer 15B.

The transparent layers 17R, 17G, and 17B are formed using a transparent dielectric material or a transparent electrical conductor material, for example. For example, silicon oxide (SiO₂), silicon oxynitride (SiON), silicon nitride (SiN), or other materials may be given as a transparent dielectric material used in the transparent layers 17R, 17G, and 17B. The transparent layers 17R, 17G, and 17B may be formed using a low-refractive-index material such as magnesium fluoride (MgF) or sodium fluoride (NaF), for example. As the transparent electrical conductor material used for the transparent layers 17R, 17G, and 17B, for example, ITO, IZO, or other materials may be given. The thickness of the transparent layers 17R, 17G, and 17B is greater than or equal to 50 nm but less than or equal to 1000 nm, for example.

The transparent layers 18R, 18G, and 18B are formed using a transparent dielectric material, for example. For example, SiO₂, SiON, SiN, or other materials may be given as a transparent dielectric material used in the transparent layers 18R, 18G, and 18B. The transparent layers 18R, 18G, and 18B are in contact with the transparent layers 17R, 17G, and 17B. The interfaces between the transparent layers 18R, 18G, and 18B and the transparent layers 17R, 17G, and 17B are reflection interfaces due to the differences in refractive indexes between the transparent layers 18R, 18G, and 18B and the transparent layers 17R, 17G, and 17B. These reflection interfaces are, for example, each configured by an interface having a difference in refractive indexes of 0.15 or more. In a case where the transparent layers 17R, 17G, and 17B include SiON (refractive index: approximately 1.58), the transparent layers 18R, 18G, and 18B include SiN (refractive index: approximately 2.05), for example. The thickness of the transparent layers 18R, 18G, and 18B is greater than or equal to 500 nm but less than or equal to 10000 nm, for example. The transparent layers 18R, 18G, and 18B may, for example, be formed from a transparent electrically conductive material, a transparent electrically insulating material, a resin material, glass, or other materials. The transparent layers 18R, 18G, and 18B may be formed from air. By providing such layers, it is possible to prevent interference from outside with respect to the resonator structure configured between the electrode layers 12R, 12G, and 12B and the abovementioned reflection interface.

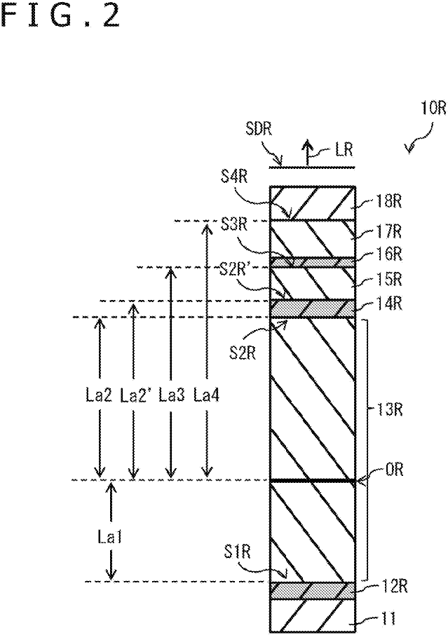

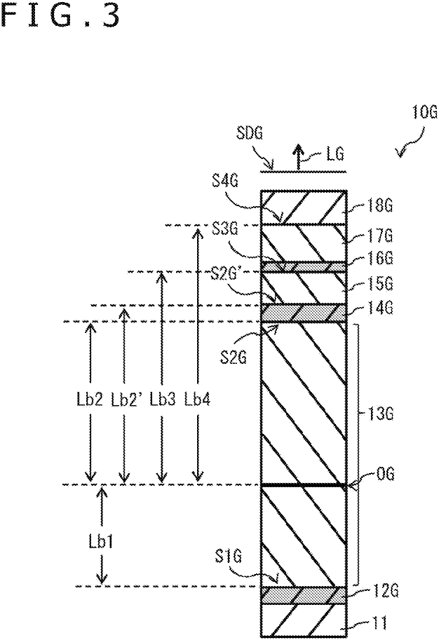

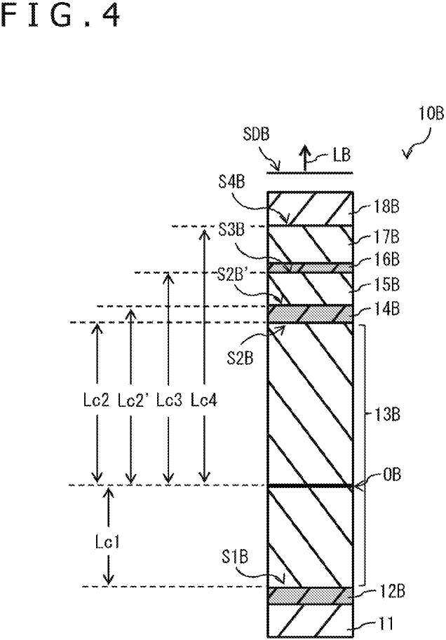

Next, description is given regarding the resonator structure of the red-light-emitting section 10R, the green-light-emitting section 10G, and the blue-light-emitting section 10B. FIG. 2 is a cross-sectional view representing a configuration of the red-light-emitting section 10R. FIG. 3 is a cross-sectional view representing a configuration of the green-light-emitting section 10G. FIG. 4 is a cross-sectional view representing a configuration of the blue-light-emitting section 10B.

The red-light-emitting section 10R has, from the substrate 11 side, a first reflection interface S1R, a second lower (light source side) reflection interface S2R, a second upper (light extraction side) reflection interface S2R′, a third reflection interface S3R, a fourth reflection interface S4R, and a light extraction surface SDR, in this order. At this point, an interference structure (microcavity structure) is formed according to the structure that includes the first reflection interface S1R, the second lower reflection interface S2R, the second upper reflection interface S2R′, the third reflection interface S3R, and the fourth reflection interface S4R. A light emission center OR for the red-light-emitting layer 131R is provided between the first reflection interface S1R and the second lower reflection interface S2R. In other words, the red-light-emitting layer 131R is provided between the first reflection interface S1R and the light extraction surface SDR which face each other. The first reflection interface S1R is the interface between the electrode layer 12R and the red organic layer 13R. The second lower reflection interface S2R is the interface between the red organic layer 13R and the metal layer 14R. The second upper reflection interface S2R′ is the interface between the metal layer 14R and the transparent layer 15R. The third reflection interface S3R is the interface between the transparent layer 15R and the metal layer 16R. The fourth reflection interface S4R is the interface between the transparent layer 17R and the transparent layer 18R. The light extraction surface SDR is the outermost surface of the red-light-emitting section 10R. The outermost surface of the red-light-emitting section 10R is in contact with an air layer, for example. Light emitted from the red-light-emitting section 10R is extracted from the light extraction surface SDR via the metal layer 14R, the transparent layer 15R, the metal layer 16R, the transparent layer 17R, and the transparent layer 18R.

The green-light-emitting section 10G has, from the substrate 11 side, a first reflection interface S1G, a second lower (light source side) reflection interface S2G, a second upper (light extraction side) reflection interface S2G′, a third reflection interface S3G, a fourth reflection interface S4G, and a light extraction surface SDG, in this order. At this point, an interference structure (microcavity structure) is formed according to the structure that includes the first reflection interface S1G, the second lower reflection interface S2G, the second upper reflection interface S2G′, the third reflection interface S3G, and the fourth reflection interface S4G. A light emission center OG for the green-light-emitting layer 131G is provided between the first reflection interface S1G and the second reflection interface S2G. In other words, the green-light-emitting layer 131G is provided between the first reflection interface S1G and the light extraction surface SDG which face each other. The first reflection interface S1G is the interface between the electrode layer 12G and the green organic layer 13G. The second lower reflection interface S2G is the interface between the green organic layer 13G and the metal layer 14G. The second upper reflection interface S2G′ is the interface between the metal layer 14G and the transparent layer 15G. The third reflection interface S3G is the interface between the transparent layer 15G and the metal layer 16G. The fourth reflection interface S4G is the interface between the transparent layer 17G and the transparent layer 18G. The light extraction surface SDG is the outermost surface of the green-light-emitting section 10G. The outermost surface of the green-light-emitting section 10G is in contact with an air layer, for example. Light emitted from the green-light-emitting section 10G is extracted from the light extraction surface SDG via the metal layer 14G, the transparent layer 15G, the metal layer 16G, the transparent layer 17G, and the transparent layer 18G.

The blue-light-emitting section 10B has, from the substrate 11 side, a first reflection interface S1B, a second lower (light source side) reflection interface S2B, a second upper (light extraction side) reflection interface S2B′, a third reflection interface S3B, a fourth reflection interface S4B, and a light extraction surface SDB, in this order. At this point, an interference structure (microcavity structure) is formed according to the structure that includes the first reflection interface S1B, the second lower reflection interface S2B, the second upper reflection interface S2B′, the third reflection interface S3B, and the fourth reflection interface S4B. A light emission center OB is provided between the first reflection interface S1B and the second lower reflection interface S2B. In other words, the blue-light-emitting layer 131B is provided between the first reflection interface S1B and the light extraction surface SDB which face each other. The first reflection interface S1B is the interface between the electrode layer 12B and the blue organic layer 13B. The second lower reflection interface S2B is the interface between the blue organic layer 13B and the metal layer 14B. The second upper reflection interface S2B′ is the interface between the metal layer 14B and the transparent layer 15B. The third reflection interface S3B is the interface between the transparent layer 15B and the metal layer 16B. The fourth reflection interface S4B is the interface between the transparent layer 17B and the transparent layer 18B. The light extraction surface SDB is the outermost surface of the blue-light-emitting section 10B. The outermost surface of the blue-light-emitting section 10B is in contact with an air layer, for example. Light emitted from the blue-light-emitting section 10B is extracted from the light extraction surface SDB via the metal layer 14B, the transparent layer 15B, the metal layer 16B, the transparent layer 17B, and the transparent layer 18B.

The first reflection interfaces S1R, S1G, and S1B, the second lower reflection interfaces S2R, S2G, and S2B, the second upper reflection interfaces S2R′, S2G′, and S2B′, and the third reflection interfaces S3R, S3G, and S3B are formed using a reflective film that is made of metal. The fourth reflection interfaces S4R, S4G, and S4B are formed according to the differences in refractive indexes between the plurality of types of transparent material layers that differ from metal reflective films.

### First Reflection Interfaces S1R, S1G, and S1B

The electrode layers 12R, 12G, and 12B are formed using aluminum (Al), which has a refractive index of 0.73 and an extinction coefficient of 5.91, and the red organic layer 13R, the green organic layer 13G, and the blue organic layer 13B are formed using a material that has a refractive index of 1.75. At this point, the first reflection interface S1R is disposed at a position that is an optical distance La1 from the light emission center OR, the first reflection interface S1G is disposed at a position that is an optical distance Lb1 from the light emission center OG, and the first reflection interface S1B is disposed at a position that is an optical distance Lc1 from the light emission center OB.

The optical distance La1 is set so as to use interference between the first reflection interface S1R and the light emission center OR to strengthen light having a central wavelength λa of the emission spectrum for the red-light-emitting layer 131R. The optical distance Lb1 is set so as to use interference between the first reflection interface S1G and the light emission center OG to strengthen light having a central wavelength λb of the emission spectrum for the green-light-emitting layer 131G. The optical distance Lc1 is set so as to use interference between the first reflection interface S1B and the light emission center OB to strengthen light having a central wavelength λc of the emission spectrum for the blue-light-emitting layer 131B.

Specifically, the optical distances La1, Lb1, and Lc1 satisfy the following formulae (1) through (6).

$$2 \text{La1} / \text{λ} \text{a1} \text{+} \text{φ} \text{a1} / \left(2 \text{π}\right) = \text{Na}$$

$$\text{λ} \text{a - 150 <} \text{λ} \text{a1 <} \text{λ} \text{a + 80}$$

$$2 \text{Lb1} / \text{λ} \text{b1 +} \text{φ} \text{b1} / \left(2 \text{π}\right) = \text{Nb}$$

$$\text{λ} \text{b - 150 <} \text{λ} \text{b1 <} \text{λ} \text{b + 80}$$

$$2 \text{Lc1} / \text{λ} \text{c1} + \text{φ} \text{c1} / \left(2 \text{π}\right) = \text{Nc}$$

$$\text{λ} \text{c - 150 <} \text{λ} \text{c1 <} \text{λ} \text{c + 80}$$

Na, Nb, and Nc: integers that are greater than or equal to 0
Unit for λa, λa1, λb, λb1, λc, and λc1: nm
φa1: phase change when light emitted from the red-light-emitting layer 131R is reflected by the first reflection interface S1R
φb1: phase change when light emitted from the green-light-emitting layer 131G is reflected by the first reflection interface S1G
φc1: phase change when light emitted from the blue-light-emitting layer 131B is reflected by the first reflection interface S1B
λa1: wavelength that satisfies the formula (2)
λb1: wavelength that satisfies the formula (4)
λc1: wavelength that satisfies the formula (6)

φa1, φb1, and φc1 can be calculated using n0 and k from a complex refractive index N = n0 - jk (n0: refractive index, k: extinction coefficient) for the constituent material of the electrode layers 12R, 12G, and 12B, as well as the refractive indexes of the red organic layer 13R, the green organic layer 13G, and the blue organic layer 13B (for example, refer to Principles of Optics, Max Born and Emil Wolf, 1974 (PERGAMON PRESS) or other literature). The refractive index of each constituent material can be measured using a spectroscopic ellipsometry measurement apparatus.

There is a risk that what is called a microcavity (microresonator) effect cannot be achieved when values for Na, Nb, and Nc are large. Accordingly, it is desirable to have Na = 0, Nb = 0, and Nc = 0. In a case where the optical distance La1 satisfies the above formulae (1) and (2), it is possible to greatly shift λa1 from the central wavelength λa. Similarly, in a case where the optical distance Lb1 satisfies the above formulae (3) and (4), it is possible to greatly shift λb1 from the central wavelength λb. In a case where the optical distance Lc1 satisfies the above formulae (5) and (6), it is also possible to greatly shift λc1 from the central wavelength λc.

### Second Lower Reflection Interfaces S2R, S2G, and S2B

The red organic layer 13R, the green organic layer 13G, and the blue organic layer 13B are formed using a material having a refractive index of 1.75, and the metal layers 14R, 14G, and 14B are formed using silver (Ag) having a refractive index of 0.13 and an extinction coefficient of 3.96. At this point, the second lower reflection interface S2R is disposed at a position that is an optical distance La2 from the light emission center OR, the second lower reflection interface S2G is disposed at a position that is an optical distance Lb2 from the light emission center OG, and the second lower reflection interface S2B is disposed at a position that is an optical distance Lc2 from the light emission center OB.

The optical distance La2 is set so as to use interference between the second lower reflection interface S2R and the light emission center OR to strengthen light having the central wavelength λa of the emission spectrum for the red-light-emitting layer 131R. The optical distance Lb2 is set so as to use interference between the second lower reflection interface S2G and the light emission center OG to strengthen light having the central wavelength λb of the emission spectrum for the green-light-emitting layer 131G. The optical distance Lc2 is set so as to use interference between the second lower reflection interface S2B and the light emission center OB to strengthen light having the central wavelength λc of the emission spectrum for the blue-light-emitting layer 131B.

Specifically, the optical distances La2, Lb2, and Lc2 satisfy the following formulae (7) through (12).

$$2 \text{La2} / \text{λ} \text{a2} \text{+} \text{φ} \text{a2} / \left(2 \text{π}\right) = \text{Ma}$$

$$\text{λ} \text{a - 80 <} \text{λ} \text{a2 <} \text{λ} \text{a + 80}$$

$$2 \text{Lb2} / \text{λ} \text{b2} \text{+} \text{φ} \text{b2} / \left(2 \text{π}\right) = \text{Mb}$$

$$\text{λ} \text{b - 80 <} \text{λ} \text{b2 <} \text{λ} \text{b + 80}$$

$$2 \text{Lc2} / \text{λ} \text{c2} \text{+} \text{φ} \text{c2} / \left(2 \text{π}\right) = \text{Mc}$$

$$\text{λ} \text{c - 80 <} \text{λ} \text{c2 <} \text{λ} \text{c + 80}$$

Ma, Mb, and Mc: integers greater than or equal to 0
Unit for λa, λa2, λb, λb2, λc, and λc2: nm
φa2: phase change when light emitted from the red-light-emitting layer 131R is reflected by the second lower reflection interface S2R
φb2: phase change when light emitted from the green-light-emitting layer 131G is reflected by the second lower reflection interface S2G
φc2: phase change when light emitted from the blue-light-emitting layer 131B is reflected by the second lower reflection interface S2B
$$\text{λ} \text{a2: wavelength that satisfies the formula}$$
$$\text{λ} \text{b2: wavelength that satisfies the formula}$$
$$\text{λ} \text{c2: wavelength that satisfies the formula}$$

φa2, φb2, and φc2 can be obtained by a similar method to that for φa1, φb1, and φc1. There is a risk that what is called a microcavity (microresonator) effect cannot be achieved when values for Ma, Mb, and Mc are large. Accordingly, it is desirable that Ma = 1, Mb = 1, and Mc = 1 be obtained.

In a case where the optical distance La1 satisfies the above formulae (1) and (2) and the optical distance La2 satisfies the above formulae (7) and (8), a peak for transmittance occurs at a predetermined wavelength in accordance with an amplification effect by the first reflection interface S1R and the second lower reflection interface S2R. In a case where the optical distance Lb1 satisfies the above formulae (3) and (4) and the optical distance Lb2 satisfies the above formulae (9) and (10), a peak for transmittance occurs at a predetermined wavelength in accordance with an amplification effect by the first reflection interface S1G and the second lower reflection interface S2G. In a case where the optical distance Lc1 satisfies the above formulae (5) and (6) and a case where the optical distance Lc2 satisfies the above formulae (11) and (12), a peak for transmittance occurs at a predetermined wavelength in accordance with an amplification effect by the first reflection interface S1B and the second lower reflection interface S2B.

### Second Upper Reflection Interfaces S2R′, S2G′, and S2B′

The red organic layer 13R, the green organic layer 13G, and the blue organic layer 13B are formed using a material having a refractive index of 1.75, and the metal layers 14R, 14G, and 14B are formed using silver (Ag) having a refractive index of 0.13 and an extinction coefficient of 3.96. At this point, the second upper reflection interface S2R′ is disposed at a position that is an optical distance La2′ from the light emission center OR, the second upper reflection interface S2G′ is disposed at a position that is an optical distance Lb2′ from the light emission center OG, and the second upper reflection interface S2B′ is disposed at a position that is an optical distance Lc2′ from the light emission center OB.

The optical distance La2′ is set so as to use interference between the second upper reflection interface S2R′ and the light emission center OR to weaken light having the central wavelength λa of the emission spectrum for the red-light-emitting layer 131R. The optical distance Lb2′ is set so as to use interference between the second upper reflection interface S2G′ and the light emission center OG to weaken light having the central wavelength λb of the emission spectrum for the green-light-emitting layer 131G. The optical distance Lc2′ is set so as to use interference between the second upper reflection interface S2B′ and the light emission center OB to weaken light having the central wavelength λc of the emission spectrum for the blue-light-emitting layer 131B.

Specifically, the optical distances La2′, Lb2′, and Lc2′ satisfy the following formulae (13) through (18).

$$2 \text{La} {\text{2}}^{′} / \text{λ} \text{a} {\text{2}}^{′} + \text{φ} \text{a} {\text{2}}^{′} / \left(2 \text{π}\right) = \text{Ma+} 1 / 2$$

$$\text{λ} \text{a - 80 <} \text{λ} \text{a} {\text{2}}^{′} \text{<} \text{λ} \text{a + 80}$$

$$2 \text{Lb} {\text{2}}^{′} / \text{λ} \text{b} {\text{2}}^{′} \text{+} \text{φ} \text{b} {\text{2}}^{′} / \left(2 \text{π}\right) = \text{Mb +} 1 / 2$$

$$\text{λ} \text{b - 80 <} \text{λ} \text{b} {\text{2}}^{′} \text{<} \text{λ} \text{b + 80}$$

$$2 \text{Lc} {\text{2}}^{′} / \text{λ} \text{c} {\text{2}}^{′} \text{+} \text{φ} \text{c} {\text{2}}^{′} / \left(2 \text{π}\right) = \text{Mc +} 1 / 2$$

$$\text{λ} \text{c - 80 <} \text{λ} \text{c} {\text{2}}^{′} \text{<} \text{λ} \text{c + 80}$$

Ma, Mb, and Mc: integers greater than or equal to 0
Unit for λa, λa2′, λb, λb2′, λc, and λc2′: nm
φa2′: phase change when light emitted from the red-light-emitting layer 131R is reflected by the second upper reflection interface S2R′
φb2′: phase change when light emitted from the green-light-emitting layer 131G is reflected by the second upper reflection interface S2G′
φc2′: phase change when light emitted from the blue-light-emitting layer 131B is reflected by the second upper reflection interface S2B′
$$\text{λ} \text{a} {\text{2}}^{′} \text{: wavelength that satisfies the formula}$$
$$\text{λ} \text{b} {\text{2}}^{′} \text{: wavelength that satisfies the formula}$$
$$\text{λ} \text{c} {\text{2}}^{′} \text{: wavelength that satisfies the formula}$$

φa2′, φb2′, and φc2′ can be obtained by a similar method to that for φa1, φb1, and φc1. In a case where the optical distances La2′, Lb2′, and Lc2′ satisfy the above formulae (13) through (18), it is possible to adjust a light-emitting state for each light-emitting section (the red-light-emitting section 10R, the green-light-emitting section 10G, and the blue-light-emitting section 10B). In this manner, reflection by the second upper reflection interface S2R′ is added, whereby light generated by the red-light-emitting layer 131R is weakened, and the half width of the spectrum widens. In addition, reflection by the second upper reflection interface S2G′ is added, whereby light generated by the green-light-emitting layer 131G is weakened, and the half width of the spectrum widens. Reflection by the second upper reflection interface S2B′ is added, whereby light generated by the blue-light-emitting layer 131B is weakened, and the half width of the spectrum widens.

### Third Reflection Interfaces S3R, S3G, and S3B

The optical distance La3 is, for example, set so as to use interference between the third reflection interface S3R and the light emission center OR to weaken light having the central wavelength λa of the emission spectrum for the red-light-emitting layer 131R. At this point, the optical distance between the second lower reflection interface S2R and the third reflection interface S3R is less than or equal to the central wavelength λa for light emitted from the red-light-emitting layer 131R. The optical distance Lb3 is, for example, set so as to use interference between the third reflection interface S3G and the light emission center OG to weaken light having the central wavelength λb of the emission spectrum for the green-light-emitting layer 131G. At this point, the optical distance between the second lower reflection interface S2G and the third reflection interface S3G is less than or equal to the central wavelength λb for light emitted from the green-light-emitting layer 131G. The optical distance Lc3 is, for example, set so as to use interference between the third reflection interface S3B and the light emission center OB to strengthen light having the central wavelength λc of the emission spectrum for the blue-light-emitting layer 131B. At this point, the optical distance between the second lower reflection interface S2B and the third reflection interface S3B is less than or equal to the central wavelength λc for light emitted from the blue-light-emitting layer 131B.

The optical distances La3, Lb3, and Lc3 satisfy the following formulae (19) through (24), for example.

$$2 \text{La3} / \text{λ} \text{a3} \text{+} \text{φ} \text{a3} / \left(2 \text{π}\right) = \text{Ka +} 1 / 2$$

$$\text{λ} \text{a - 150 <} \text{λ} \text{a3 <} \text{λ} \text{a + 150}$$

$$2 \text{Lb3} / \text{λ} \text{b3} \text{+} \text{φ} \text{b3} / \left(2 \text{π}\right) = \text{Kb +} 1 / 2$$

$$\text{λ} \text{b - 150 <} \text{λ} \text{b3 <} \text{λ} \text{b + 150}$$

$$2 \text{Lc3} / \text{λ} \text{c3} \text{+} \text{φ} \text{c3} / \left(2 \text{π}\right) = \text{Kc}$$

$$\text{λ} \text{c - 150 <} \text{λ} \text{c3 <} \text{λ} \text{c + 150}$$

Ka, Kb, and Kc: integers greater than or equal to 0
Unit for λa, λa3, λb, λb3, λc, and λc3: nm
φa3: phase change when light emitted from the red-light-emitting layer 131R is reflected by the third reflection interface S3R
φb3: phase change when light emitted from the green-light-emitting layer 131G is reflected by the third reflection interface S3G
φc3: phase change when light emitted from the blue-light-emitting layer 131B is reflected by the third reflection interface S3B
$$\text{λ} \text{a3: wavelength that satisfies the formula}$$
$$\text{λ} \text{b3: wavelength that satisfies the formula}$$
$$\text{λ} \text{c3: wavelength that satisfies the formula}$$

φa3, φb3, and φc3 can be obtained by a similar method to that for φa1, φb1, and φc1. In a case where the optical distances La3, Lb3, and Lc3 satisfy the above formulae (19) through (24), it is possible to adjust a light-emitting state for each light-emitting section (the red-light-emitting section 10R, the green-light-emitting section 10G, and the blue-light-emitting section 10B). In this manner, reflection by the third reflection interface S3R is added, whereby light generated by the red-light-emitting layer 131R is weakened, and the half width of the spectrum widens. In addition, reflection by the third reflection interface S3G is added, whereby light generated by the green-light-emitting layer 131G is weakened, and the half width of the spectrum widens. Reflection by the third reflection interface S3B is added, whereby light generated by the blue-light-emitting layer 131B is strengthened, and the half width of the spectrum narrows.

### Fourth Reflection Interfaces S4R, S4G, and S4B

The optical distance La4 is, for example, set so as to use interference between the fourth reflection interface S4R and the light emission center OR to weaken light having the central wavelength λa of the emission spectrum for the red-light-emitting layer 131R. At this point, the optical distance between the third reflection interface S3R and the fourth reflection interface S4R is 112 to 750 nm. This optical distance is set such that the round-trip optical distance between the third reflection interface S3R and the fourth reflection interface S4R is within a range of 0.5 to 2.0 λa. The optical distance Lb4 is, for example, set so as to use interference between the fourth reflection interface S4G and the light emission center OG to weaken light having the central wavelength λb of the emission spectrum for the green-light-emitting layer 131G. At this point, the optical distance between the third reflection interface S3G and the fourth reflection interface S4G is 112 to 750 nm. This optical distance is set such that the round-trip optical distance between the third reflection interface S3G and the fourth reflection interface S4G is within a range of 0.5 to 2.0 λb. The optical distance Lc4 is, for example, set so as to use interference between the fourth reflection interface S4B and the light emission center OB to strengthen light having the central wavelength λc of the emission spectrum for the blue-light-emitting layer 131B. At this point, the optical distance between the third reflection interface S3B and the fourth reflection interface S4B is 112 to 750 nm. This optical distance is set such that the round-trip optical distance between the third reflection interface S3B and the fourth reflection interface S4B is within a range of 0.5 to 2.0 λc.

The optical distances La4, Lb4, and Lc4 satisfy the following formulae (25) through (30), for example.

$$2 \text{La4} / \text{λ} \text{a4} \text{+} \text{φ} \text{a4} / \left(2 \text{π}\right) = \text{Kd +} 1 / 2$$

$$\text{λ} \text{a - 150 <} \text{λ} \text{a4 <} \text{λ} \text{a + 150}$$

$$2 \text{Lb4} / \text{λ} \text{b4} + \text{φ} \text{b4} / \left(2 π\right) = \text{Ke} + 1 / 2$$

$$\text{λ} \text{b} - 150 < \text{λ} \text{b4} < \text{λ} \text{b} + 150$$

$$2 \text{Lc4} / \text{λ} \text{c4} + \text{φ} \text{c4} / \left(2 π\right) = \text{Kf}$$

$$\text{λ} \text{c} - 150 < \text{λ} \text{c4} < \text{λ} \text{c} + 150$$

Kd, Ke, and Kf: integers that are greater than or equal to 0
Unit for λa, λa4, λb, λb4, λc, and λc4: nm
φa4: phase change when light emitted from the red-light-emitting layer 131R is reflected by the fourth reflection interface S4R
φb4: phase change when light emitted from the green-light-emitting layer 131G is reflected by the fourth reflection interface S4G
φc4: phase change when light emitted from the blue-light-emitting layer 131B is reflected by the fourth reflection interface S4B
$$\text{λ} \text{a4} : \text{wavelength that satisfies the formula}$$
$$\text{λ} \text{b4} : \text{wavelength that satisfies the formula}$$
$$\text{λ} \text{c4} : \text{wavelength that satisfies the formula}$$

φa4, φb4, and φc4 can be obtained by a similar method to that for φa1, φb1, and φc1. In a case where the optical distances La3, Lb3, and Lc3 satisfy the above formulae (19) through (24) and a case where the optical distances La4, Lb4, and Lc4 satisfy the above formulae (25) through (30), it is possible to adjust a light-emitting state for each light-emitting section (the red-light-emitting section 10R, the green-light-emitting section 10G, and the blue-light-emitting section 10B). In this manner, reflection by the fourth reflection interface S4R is added, whereby light generated by the red-light-emitting layer 131R is weakened, and the half width of the spectrum widens. In addition, reflection by the fourth reflection interface S4G is added, whereby light generated by the green-light-emitting layer 131G is weakened, and the half width of the spectrum widens. Reflection by the fourth reflection interface S4B is added, whereby light generated by the blue-light-emitting layer 131B is strengthened, and the half width of the spectrum narrows.

Such a light-emitting apparatus 1 can be manufactured by forming, on the substrate 11, the electrode layers 12R, 12G, and 12B, the organic layers (the red organic layer 13R, the green organic layer 13G, and the blue organic layer 13B), the metal layers 14R, 14G, and 14B, the transparent layers 15R, 15G, and 15B, the metal layers 16R, 16G, and 16B, the transparent layers 17R, 17G, and 17B, and the transparent layers 18R, 18G, and 18B, in this order. The red organic layer 13R, the green organic layer 13G, and the blue organic layer 13B may be formed using vapor deposition, or may be formed using printing. In other words, the red organic layer 13R, the green organic layer 13G, and the blue organic layer 13B may be printed layers. The metal layers 14R, 14G, and 14B may be configured by a mutually common layer. In this case, the material and thickness of the metal layers 14R, 14G, and 14B are the same as each other. The transparent layers 15R, 15G, and 15B may be configured by a mutually common layer. In this case, the material and thickness of the transparent layers 15R, 15G, and 15B are the same as each other. The metal layers 16R, 16G, and 16B may be configured by a mutually common layer. In this case, the material and thickness of the metal layers 16R, 16G, and 16B are the same as each other. The transparent layers 17R, 17G, and 17B may be configured by a mutually common layer. In this case, the material and thickness of the transparent layers 17R, 17G, and 17B are the same as each other. The transparent layers 18R, 18G, and 18B may be configured by a mutually common layer. In this case, the material and thickness of the transparent layers 18R, 18G, and 18B are the same as each other.

### Action and Effect

In the light-emitting apparatus 1 as described above, a drive current is injected into each light-emitting layer (the red-light-emitting layer 131R, the green-light-emitting layer 131G, and the blue-light-emitting layer 131B) of the red-light-emitting section 10R, the green-light-emitting section 10G, and the blue-light-emitting section 10B, through the electrode layers 12R, 12G, and 12B and the metal layers 14R, 14G, and 14B. As a result, excitons occur due to the recombination of holes and electrons in each light-emitting layer, and light emission occurs.

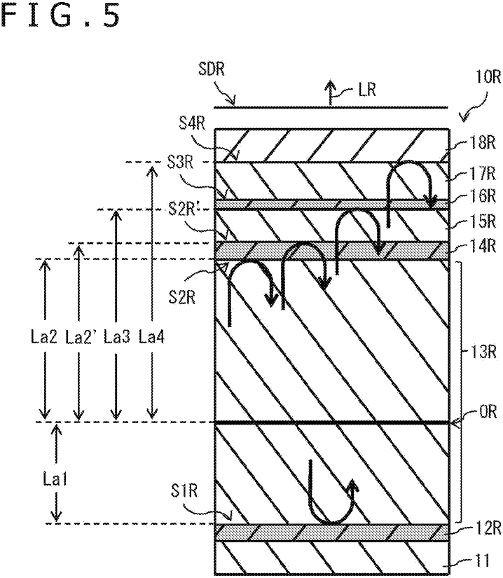

For example, as illustrated in FIG. 5, light generated in the red organic layer 13R is multiply reflected between the first reflection interface S1R and the fourth reflection interface S4R and extracted from the light extraction surface SDR. Red light LR is extracted from the light extraction surface SDR in the red-light-emitting section 10R, green light LG is extracted from the light extraction surface SDG in the green-light-emitting section 10G, and blue light LB is extracted from the light extraction surface SDB in the blue-light-emitting section 10B. Various colors are represented by an additive color resulting from the red light LR, the green light LG, and the blue light LB.

However, in a light-emitting apparatus having such a resonator structure, despite various structures having been proposed, it has been difficult to improve a light distribution characteristic.

For example, a method of setting a film thickness between a translucent electrode and a reflective electrode such that light having a desired wavelength resonates, and thereby improving light-emission efficiency has been proposed (for example, refer to PCT Patent Publication No. WO01/039554). In addition, attempts have been made to control the film thickness of an organic layer to thereby control the balance of attenuation for the three primary colors (red, green, and blue) and increase a viewing angle characteristic for a white chromaticity point (for example, refer to Japanese Patent Laid-open No. 2011-159433).

However, such a resonator structure functions as an interference filter having a narrow half width with respect to the spectrum of extracted light, and thus the above-described interference conditions change as the effective optical distance changes, when the light extraction surface is seen from a diagonal direction. Accordingly, a decrease etc. in the light-emission intensity arises due to the viewing angle, and viewing angle dependence becomes large.

In addition, a structure for reducing a chromaticity change due to a viewing angle is proposed in Japanese Patent Laid-open No. 2006-244713. However, although it might be the case where this structure can reduce the viewing angle dependence for luminance by being applied to a monochrome, it is difficult to apply this structure to a sufficiently wide wavelength band. Increasing the reflectance can be considered in order to widen the wavelength band to which application is possible, but light extraction efficiency drops remarkably in this case.

As described above, consideration can be given to a method for reducing the angle dependence by adjusting a light-emission position, positional relations within a resonator structure, etc., but there are some cases where adjustment is difficult with this method. For example, there is a case where wavelength dispersion of a refractive index arises due to the spectrum of light emitted from each light-emitting layer. Because the refractive index of a constituent material differs in accordance with each wavelength in refractive index wavelength dispersion, differences in effect arise between the resonator structures for a red organic EL element, a green organic EL element, and a blue organic EL element. For example, the peak of extracted red light becomes too steep in a red organic EL element, and the peak of extracted blue light becomes too gentle in a blue organic EL element. In this manner, when the effect of the resonator structure for each element region becomes greatly different, the angle dependence for luminance and chromaticity increases, and a light distribution characteristic decreases.

In contrast to this, in the light-emitting apparatus 1 according to an embodiment of the present embodiment, the effect that the third reflection interface S3R and the fourth reflection interface S4R have on light generated by the red-light-emitting layer 131R is mutually different from the effect that the third reflection interface S3B and the fourth reflection interface S4B have on light generated by the blue-light-emitting layer 131B. Similarly, in the light-emitting apparatus 1 according to an embodiment of the present embodiment, the effect that the third reflection interface S3G and the fourth reflection interface S4G have on light generated by the green-light-emitting layer 131G is mutually different from the effect that the third reflection interface S3B and the fourth reflection interface S4B have on light generated by the blue-light-emitting layer 131B. For example, light generated by the red-light-emitting layer 131R, the green-light-emitting layer 131G, and the blue-light-emitting layer 131B is as follows.

Light generated by the red-light-emitting layer 131R is weakened by interference between the light emission center OR of the red-light-emitting layer 131R and the second upper reflection interface S2R′, the third reflection interface S3R, and the fourth reflection interface S4R. Similarly, light generated by the green-light-emitting layer 131G is weakened by interference between the light emission center OG of the green-light-emitting layer 131G and the second upper reflection interface S2G′, the third reflection interface S3G, and the fourth reflection interface S4G. In contrast, light generated by the blue-light-emitting layer 131B is strengthened by interference between the light emission center OB of the blue-light-emitting layer 131B and the third reflection interface S3B and the fourth reflection interface S4B.

As a result, red light LR having a gentle peak is extracted from the light extraction surface SDR in the red-light-emitting section 10R, green light LG having a gentle peak is extracted from the light extraction surface SDG in the green-light-emitting section 10G, and blue light LB having a steep peak is extracted from the light extraction surface SDB in the blue-light-emitting section 10B. Therefore, the difference between the effect of the resonator structures for the red-light-emitting section 10R and the green-light-emitting section 10G and the effect of the resonator structure for the blue-light-emitting section 10B decreases, and angle dependence for chromaticity and luminance decreases. Accordingly, it is possible to improve a light distribution characteristic. In addition, the light-emitting apparatus 1, which has a high light distribution characteristic, is also suitable for a display apparatus that requires high image quality, and it is possible to improve the productivity of the display apparatus.

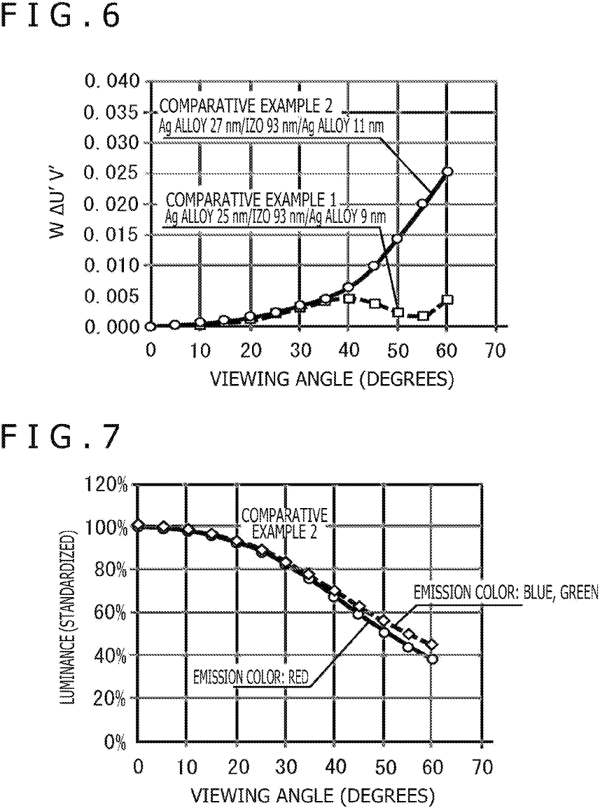

FIG. 6 represents an example of change in chromaticity due to the viewing angle for light-emitting apparatuses according to comparative examples 1 and 2. In the light-emitting apparatus according to comparative example 1, an electrode layer on a substrate side is formed by a single-layer Al Alloy, and an electrode layer on a light extraction surface side is configured by a laminate of an Ag alloy (25 nm) / IZO (93 nm) / an Ag alloy (9 nm). Further, in the light-emitting apparatus according to comparative example 2, an electrode layer on a substrate side is formed by a single-layer Al Alloy, and an electrode layer on a light extraction surface side is configured by a laminate of an Ag alloy (27 nm) / IZO (93 nm) / an Ag alloy (11 nm). FIG. 7 represents an example of change in luminance for each color due to the viewing angle for the light-emitting apparatus according to comparative example 2.

As illustrated in FIG. 6, in the light-emitting apparatus according to comparative example 1, the total thickness of the Ag alloys included in the second electrode is 34 nm, and it is understood that there is more or less no viewing angle dependence for chromaticity with this thickness. However, as illustrated in FIG. 6, in the light-emitting apparatus according to comparative example 2, the total thickness of the Ag alloys included in the second electrode is 38 nm, and it is understood that, with this thickness, the viewing angle dependence for chromaticity increases and the image quality for a display is impaired. This phenomenon is the impact of complex refractive index wavelength dispersion on metal thin films on the light extraction side, and, in conjunction with increasing film thickness, is due to the wavelength dependence strengthening as illustrated in FIG. 7, for example.

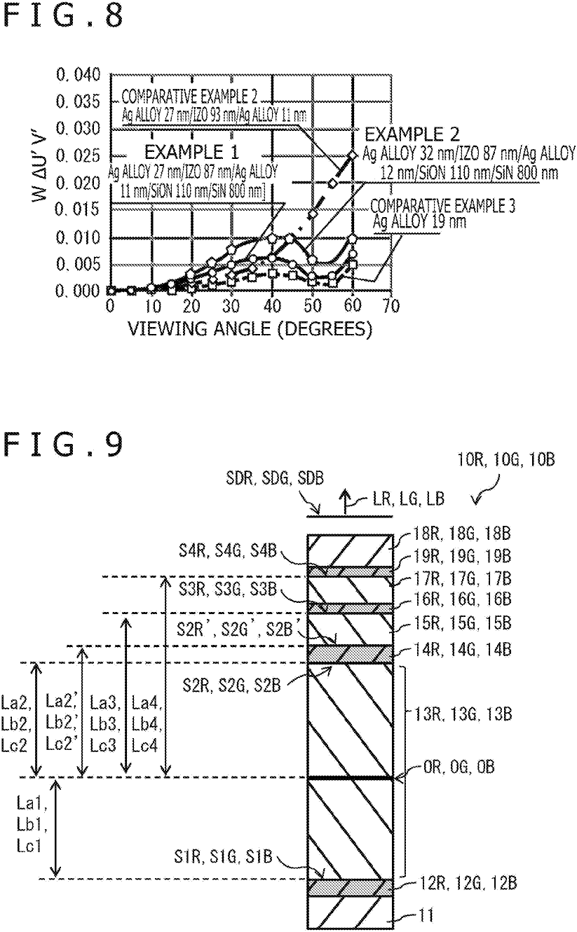

FIG. 8 represents an example of change in chromaticity due to the viewing angle for light-emitting apparatuses according to comparative examples 2 and 3 as well as examples 1 and 2. In the light-emitting apparatus according to comparative example 3, the second electrode is configured by a single-layer Ag alloy (19 nm). In the light-emitting apparatus according to example 1, the total thickness of Ag alloy included in the second electrode is 38 nm, but it is understood that the viewing angle characteristic for chromaticity is similar to the viewing angle characteristic for chromaticity in the light-emitting apparatus according to comparative example 3 and there is more or less no viewing angle dependence for chromaticity. This is due to an interference effect in accordance with provided reflection interfaces (the fourth reflection interfaces S4R, S4G, and S4B described above), which are formed by the differences in refractive indexes between the SiON layer (110 nm) and the SiN layer (800 nm) in the light-emitting apparatus according to this example. In addition, in the light-emitting apparatus according to this example, the thickness of the second electrode is doubled and the resistance is halved, in comparison to that in the light-emitting apparatus according to comparative example 3. In addition, in the light-emitting apparatus according to example 2, the total thickness of the Ag alloy included in the second electrode is 44 nm, but it is understood that the viewing angle characteristic for chromaticity is slightly inferior to example 1 and the viewing angle dependence for chromaticity is comparatively smaller.

From the above, in the present embodiment, it is possible to reduce deterioration of the viewing angle characteristic for chromaticity even in the case where a metal layer included in a cathode electrode on the side of the light extraction surfaces SDR, SDG, and SDB is made to be a thick film. Accordingly, it is possible to establish both power supply performance and a viewing angle characteristic for chromaticity.

In addition, in the present embodiment, the optical distance between the second lower reflection interface S2R and the third reflection interface S3R is less than or equal to the central wavelength λa for light emitted from the red-light-emitting layer 131R. Similarly, the optical distance between the second lower reflection interface S2G and the third reflection interface S3G is less than or equal to the central wavelength λb for light emitted from the green-light-emitting layer 131G. The optical distance between the second lower reflection interface S2B and the third reflection interface S3B is less than or equal to the central wavelength λc for light emitted from the blue-light-emitting layer 131B. As a result, it is possible to use the action of the second lower reflection interfaces S2R, S2G, and S2B and the third reflection interfaces S3R, S3G, and S3B with respect to light generated by the light-emitting layers 131R, 131G, and 131B to adjust a peak profile of the spectrum of light generated by the red-light-emitting layer 131R, the green-light-emitting layer 131G, and the blue-light-emitting layer 131B. Accordingly, it is possible to reduce deterioration of the viewing angle characteristic for chromaticity even in the case where the total thickness of a metal layer included in a cathode electrode on the side of the light extraction surfaces SDR, SDG, and SDB is made to be thicker.

In addition, in the present embodiment, the interference structure in the red-light-emitting section 10R is configured to satisfy the above formulae (1), (2), (7), (8), (13), (14), (19), and (20). Similarly, in the green-light-emitting section 10G, the interference structure is configured to satisfy the above formulae (3), (4), (9), (10), (15), (16), (21), and (22). As a result, red light LR having a gentle peak (in other words, the half width of the spectrum widens) is extracted from the light extraction surface SDR in the red-light-emitting section 10R, and green light LG having a gentle peak is extracted from the light extraction surface SDG in the green-light-emitting section 10G. As a result, it is possible to constrain sudden change to chromaticity and luminance due to the angle.

Further, in the present embodiment, the interference structure in the blue-light-emitting section 10B is configured to satisfy the above formulae (5), (6), (11), (12), (17), (18), (23), and (24). As a result, blue light LB having a steep peak is extracted from the light extraction surface SDB in the blue-light-emitting section 10B. Accordingly, the difference between the effect of the resonator structures for the red-light-emitting section 10R and the green-light-emitting section 10G and the effect of the resonator structure for the blue-light-emitting section 10B decreases, and angle dependence for chromaticity and luminance decreases. Accordingly, it is possible to improve a light distribution characteristic. In addition, the light-emitting apparatus 1, which has a high light distribution characteristic, is also suitable for a display apparatus that requires high image quality, and it is possible to improve the productivity of the display apparatus.

In addition, in the present embodiment, in each light-emitting section (the red-light-emitting section 10R, the green-light-emitting section 10G, and the blue-light-emitting section 10B), the interference structure is configured such that the first reflection interfaces S1R, S1G, and S1B and the second lower reflection interfaces S2R, S2G, and S2B strengthen light having the wavelength band of light emitted from each light-emitting layer (the red-light-emitting layer 131R, the green-light-emitting layer 131G, and the blue-light-emitting layer 131B). Furthermore, in each light-emitting section (the red-light-emitting section 10R, the green-light-emitting section 10G, and the blue-light-emitting section 10B), the interference structure is configured such that the second upper reflection interfaces S2R′, S2G′, and S2B′, the third reflection interfaces S3R, S3G, and S3B, and the fourth reflection interfaces S4R, S4G, and S4B weaken light having the wavelength band of light emitted from respective light-emitting layers (the red-light-emitting layer 131R and the green-light-emitting layer 131G) while also strengthening light having the wavelength band of light emitted from the blue-light-emitting layer 131B.

As a result, red light LR having a gentle peak is extracted from the light extraction surface SDR in the red-light-emitting section 10R, green light LG having a gentle peak is extracted from the light extraction surface SDG in the green-light-emitting section 10G, and blue light LB having a steep peak is extracted from the light extraction surface SDB in the blue-light-emitting section 10B. As a result, in a case where the difference between the effect of the resonator structures for the red-light-emitting section 10R and the green-light-emitting section 10G and the effect of the resonator structure for the blue-light-emitting section 10B decreases, the angle dependence for chromaticity and luminance decreases. Accordingly, it is possible to improve a light distribution characteristic. In addition, the light-emitting apparatus 1, which has a high light distribution characteristic, is also suitable for a display apparatus that requires high image quality, and it is possible to improve the productivity of the display apparatus.

In addition, in the present embodiment, the metal layers 14R, 14G, and 14B are thicker than the metal layers 16R, 16G, and 16B. As a result, it is possible to improve power supply performance without impairing angle dependence for chromaticity.

In addition, in the present embodiment, the total thickness of the metal layers 14R, 14G, and 14B and the metal layers 16R, 16G, and 16B is less than or equal to 44 nm. Typically, a value for ΔU′V′ (value on the vertical axis in FIG. 8) when the viewing angle is 45° being less than or equal to 0.010 is a condition for a high-quality display. Accordingly, as illustrated in FIG. 8, this condition is satisfied when the total thickness of the metal layers 14R, 14G, and 14B and the metal layers 16R, 16G, and 16B is less than or equal to 44 nm. Accordingly, the total thickness of the metal layers 14R, 14G, and 14B and the metal layers 16R, 16G, and 16B is less than or equal to 44 nm, whereby it is possible to improve power supply performance without impairing the angle dependence for chromaticity.

In addition, in the present embodiment, the substrate 11 is a circuit substrate on which a circuit (the pixel circuit 18-1 to be described) is provided for driving the red-light-emitting layer 131R, the green-light-emitting layer 131G, and the blue-light-emitting layer 131B. Here, the light-emitting apparatus 1 is a top-surface light-emission type light-emitting apparatus. As a result, light emitted from the red-light-emitting layer 131R, the green-light-emitting layer 131G, and the blue-light-emitting layer 131B is not blocked by the pixel circuit 18-1 inside the circuit substrate, and thus it is possible to achieve high light extraction efficiency.

In addition, the transparent layers 15R, 15G, and 15B are transparent electrical conductor layers in the present embodiment. As a result, the metal layers 14R, 14G, and 14B, the transparent layers 15R, 15G, and 15B, and the metal layers 16R, 16G, and 16B are electrically connected to each other, and function as electrodes (cathode electrodes) on the side of the light extraction surfaces SDR, SDG, and SDB. As a result, it is possible to increase the total thickness of the electrode (cathode electrode) on the side of the light extraction surfaces SDR, SDG, and SDB. Accordingly, it is possible to improve power supply performance without impairing angle dependence for chromaticity.

In addition, in the present embodiment, it is desirable for the red-light-emitting layer 131R, the green-light-emitting layer 131G, and the blue-light-emitting layer 131B to be printed layers. Differences in thickness in accordance with a region are more likely to occur for organic layers due to going through a drying step. In other words, a film thickness distribution is more likely to occur in organic layers. In contrast, in the present embodiment, the red-light-emitting layer 131R, the green-light-emitting layer 131G, and the blue-light-emitting layer 131B are made to be printed layers, whereby it is possible to adjust for differences in the effect of the resonator structure for each light-emitting element caused by a film thickness distribution for the red-light-emitting layer 131R, the green-light-emitting layer 131G, and the blue-light-emitting layer 131B.

### 2. Variations

Description is given below regarding variations of the present embodiment, but, in the following description, the same reference symbol is added to components that are the same as those in the embodiment described above, and description thereof is omitted, as appropriate.

### Variation A

In the embodiment described above, for example, as illustrated in FIG. 9, the light-emitting sections (the red-light-emitting section 10R, the green-light-emitting section 10G, and the blue-light-emitting section 10B) may have metal layers 19R, 19G, and 19B between the transparent layers 17R, 17G, and 17B and the transparent layers 18R, 18G, and 18B. At this time, the transparent layers 17R, 17G, and 17B are formed using a transparent electrical conductor material. As the transparent electrical conductor material used for the transparent layers 17R, 17G, and 17B, for example, ITO, IZO, or other materials may be given.

A laminate (a second electrode) that includes the metal layer 14R, the transparent layer 15R, the metal layer 16R, the transparent layer 17R, and the metal layer 19R is a cathode electrode that forms a pair with the electrode layer 12R, and also functions as a reflective layer. A laminate (a second electrode) that includes the metal layer 14G, the transparent layer 15G, the metal layer 16G, the transparent layer 17G, and the metal layer 19G is a cathode electrode that forms a pair with the electrode layer 12G, and also functions as a reflective layer. A laminate (a second electrode) that includes the metal layer 14B, the transparent layer 15B, the metal layer 16B, the transparent layer 17B, and the metal layer 19B is a cathode electrode that forms a pair with the electrode layer 12B, and also functions as a reflective layer.

The metal layers 19R, 19G, and 19B are formed using a metal material that has a high reflectance. For example, magnesium (Mg), silver (Ag), an alloy of these, or other materials may be given as a metal material used for the metal layers 19R, 19G, and 19B. The total thickness of the metal layers 14R, 14G, and 14B, the metal layers 16R, 16G, and 16B, and the metal layers 19R, 19G, and 19B is greater than or equal to 38 nm, for example. The metal layers 19R, 19G, and 19B have a thickness of, for example, greater than or equal to 5 nm but less than or equal to 20 nm, which enables the interface on the light source side of the metal layers 19R, 19G, and 19B to be viewed as substantially the same as the interface on the light extraction side of the metal layers 19R, 19G, and 19B in a later-described interference structure. The metal layer 19R is electrically connected to the metal layer 16R via the transparent layer 17R. The metal layer 19G is electrically connected to the metal layer 16G via the transparent layer 17G. The metal layer 19B is electrically connected to the metal layer 16B via the transparent layer 17B.

In the present variation, the fourth reflection interfaces S4R, S4G, and S4B are interfaces on the light source side for the metal layers 19R, 19G, and 19B. At this point, an interference structure is formed according to the structure that includes the first reflection interface S1R, the second lower reflection interface S2R, the second upper reflection interface S2R′, the third reflection interface S3R, and the fourth reflection interface S4R. In addition, an interference structure is formed according to the structure that includes the first reflection interface S1G, the second lower reflection interface S2G, the second upper reflection interface S2G′, the third reflection interface S3G, and the fourth reflection interface S4G. In addition, an interference structure is formed according to the structure that includes the first reflection interface S1B, the second lower reflection interface S2B, the second upper reflection interface S2B′, the third reflection interface S3B, and the fourth reflection interface S4B. Even in such a case, it is possible to achieve a similar effect to the embodiment described above.

In the present variation, when the thickness of the metal layers 14R, 14G, and 14B is 30 nm, the thickness of the metal layers 16R, 16G, and 16B is 11 nm, and the thickness of the metal layers 19R, 19G, and 19B is 10 nm (in other words, when the total thickness of the metal layers 14R, 14G, and 14B, the metal layers 16R, 16G, and 16B, and the metal layers 19R, 19G, and 19B is 51 nm), the value of ΔU′V′ (value on the vertical axis in FIG. 8) when the viewing angle is 45° will be 0.020. A graph of viewing angle dependence for this time on the whole matches example 2 in FIG. 8. A value for ΔU′V′ (value on the vertical axis in FIG. 8) when the viewing angle is 45° being less than or equal to 0.020 is a condition for a relatively high-quality display. Accordingly, the total thickness of the metal layers 14R, 14G, and 14B, the metal layers 16R, 16G, and 16B, and the metal layers 19R, 19G, and 19B is less than or equal to 51 nm, whereby it is possible to improve power supply performance without impairing angle dependence for chromaticity.

### Variation B

In the embodiment described above, for example, as illustrated in FIG. 10, each light-emitting section (the red-light-emitting section 10R, the green-light-emitting section 10G, and the blue-light-emitting section 10B) may have, between the transparent layers 17R, 17G, and 17B and the transparent layers 18R, 18G, and 18B, transparent layers 21R, 21G, and 21B that are in contact with the transparent layers 17R, 17G, and 17B and the transparent layers 18R, 18G, and 18B.

The transparent layers 21R, 21G, and 21B are formed using a transparent dielectric material, for example. For example, SiO₂, SiON, SiN, or other materials may be given as a transparent dielectric material used in the transparent layers 21R, 21G, and 21B. The interfaces between the transparent layers 17R, 17G, and 17B and the transparent layers 21R, 21G, and 21B are reflection interfaces (the fourth reflection interfaces S4R, S4G, and S4B) due to the differences in refractive indexes between the transparent layers 17R, 17G, and 17B and the transparent layers 21R, 21G, and 21B. The fourth reflection interfaces S4R, S4G, and S4B are, for example, configured by interfaces having differences in refractive indexes of 0.15 or more. The interfaces between the transparent layers 21R, 21G, and 21B and the transparent layers 18R, 18G, and 18B are reflection interfaces (the fifth reflection interfaces S5R, S5G, and S5B) due to the differences in refractive indexes between the transparent layers 21R, 21G, and 21B and the transparent layers 18R, 18G, and 18B. The fifth reflection interfaces S5R, S5G, and S5B are, for example, configured by interfaces having differences in refractive indexes of 0.15 or more. The thickness of the transparent layers 21R, 21G, and 21B is greater than or equal to 50 nm but less than or equal to 1000 nm, for example. The transparent layers 21R, 21G, and 21B may, for example, be formed from a transparent electrically conductive material, a transparent electrically insulating material, a resin material, glass, or other materials.

An interference structure is formed according to the structure that includes the first reflection interface S1R, the second lower reflection interface S2R, the second upper reflection interface S2R′, the third reflection interface S3R, the fourth reflection interface S4R, and the fifth reflection interface S5R. An interference structure is formed according to the structure that includes the first reflection interface S1G, the second lower reflection interface S2G, the second upper reflection interface S2G′, the third reflection interface S3G, the fourth reflection interface S4G, and the fifth reflection interface S5G. An interference structure is formed according to the structure that includes the first reflection interface S1B, the second lower reflection interface S2B, the second upper reflection interface S2B′, the third reflection interface S3B, the fourth reflection interface S4B, and the fifth reflection interface S5B.

In the present variation, reflection by the fifth reflection interfaces S5R, S5G, and S5B is added, whereby it is possible to adjust the peak profile for the spectrum of light generated by the red-light-emitting layer 131R, the green-light-emitting layer 131G, and the blue-light-emitting layer 131B to a desired profile. As a result, for example, it is possible to constrain sudden change to chromaticity and luminance due to an angle. In addition, for example, the spectrum of light generated by a light-emitting layer is caused to have a steep peak, whereby it is possible to improve the light extraction efficiency. In addition, it is possible to improve a chromaticity point.

### Application Examples

Description is given below regarding an application example for the light-emitting apparatus 1 described in the embodiment set forth above.

### Application Example A

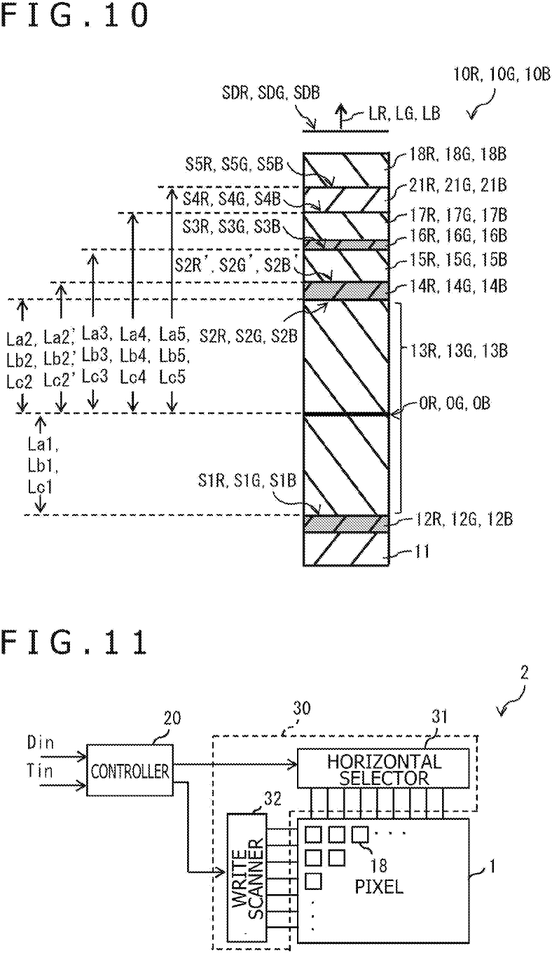

FIG. 11 represents an example of an approximate configuration of a display apparatus 2, which is an application example for the light-emitting apparatus 1 according to the above-described embodiment and variations thereof. FIG. 12 represents an example of a circuit configuration of each pixel 18 provided in the display apparatus 2. The display apparatus 2 is provided with, for example, the light-emitting apparatus 1, a controller 20, and a driver 30. The driver 30 is mounted to an outer edge portion of the light-emitting apparatus 1, for example. The light-emitting apparatus 1 has a plurality of pixels 18 disposed in a matrix shape. The controller 20 and the driver 30 drive the light-emitting apparatus 1 (a plurality of pixels 18) on the basis of an image signal Din and a synchronization signal Tin that are inputted from an external unit.

### Light-Emitting Apparatus 1

Each pixel 18 is subjected to active matrix driving by the controller 20 and the driver 30, whereby the light-emitting apparatus 1 displays an image based on the image signal Din and the synchronization signal Tin that are inputted from the external unit. The light-emitting apparatus 1 has a plurality of scan lines WSL extending in a row direction, a plurality of signal lines DTL and a plurality of power supply lines DSL that both extend in a column direction, and the plurality of pixels 18 that are disposed in a matrix shape.

The scan lines WSL are used for selection of respective pixels 18 and supply the pixels 18 with a selection pulse for selecting each predetermined unit (for example, a pixel row) of the pixels 18. The signal lines DTL are used to supply the pixels 18 with a signal voltage Vsig which corresponds to an image signal Din, and supply the pixels 18 with a data pulse that includes the signal voltage Vsig. The power supply lines DSL supply the pixels 18 with power.

The plurality of pixels 18 provided in the light-emitting apparatus 1 include pixels 18 for emitting red light, pixels 18 for emitting green light, and pixels 18 for emitting blue light. Below, a pixel 18 that emits red light is referred to as a pixel 18r, a pixel 18 that emits green light is referred to as a pixel 18g, and a pixel 18 that emits blue light is referred to as a pixel 18b. In the plurality of pixels 18, the pixels 18r, 18g, and 18b configure display pixels that are display units for a color image. Note that, for example, each display pixel may also include a pixel 18 that emits another color (for example, white, yellow, or other color). Accordingly, each predetermined number of the plurality of pixels 18 provided in the light-emitting apparatus 1 are grouped as a display pixel. In each display pixel, the plurality of pixels 18 are disposed along a line in a predetermined direction (for example, a row direction).

Each signal line DTL is connected to an output end of a later-described horizontal selector 31. For example, the plurality of signal lines DTL are allocated one at a time to each pixel column. Each scan line WSL is connected to an output end of a later-described write scanner 32. For example, each of the plurality of scan lines WSL is allocated to each pixel row. Each power supply line DSL is connected to an output end of a power supply. For example, each of the plurality of power supply lines DSL is allocated to each pixel row.

Each pixel 18 has a pixel circuit 18-1 and an organic electroluminescent section 18-2. The organic electroluminescent section 18-2 corresponds to a light-emitting section (for example, the red-light-emitting section 10R, the green-light-emitting section 10G, and the blue-light-emitting section 10B) according to the above-described embodiment and variations thereof.

The pixel circuit 18-1 controls the start and stop of light emission by the organic electroluminescent section 18-2. The pixel circuit 18-1 has a function of holding a voltage written to each pixel 18 by a write scan. The pixel circuit 18-1 is, for example, configured to include a drive transistor Tr1, a write transistor Tr2, and a storage capacitor Cs.

The write transistor Tr2 controls application, to the gate of the drive transistor Tr1, of a signal voltage Vsig corresponding to the image signal Din. Specifically, the write transistor Tr2 samples the voltage of the signal line DTL, and writes a voltage obtained by sampling to the gate of the drive transistor Tr1. The drive transistor Tr1 is connected in series to the organic electroluminescent section 18-2. The drive transistor Tr1 drives the organic electroluminescent section 18-2. The drive transistor Tr1 controls a current flowing to the organic electroluminescent section 18-2 according to the magnitude of the voltage sampled by the write transistor Tr2. The storage capacitor Cs holds a predetermined voltage between the gate and source of the drive transistor Tr1. The storage capacitor Cs has a role of holding the voltage Vgs between the gate and source of the drive transistor Tr1 constant during a predetermined time period. Note that the pixel circuit 18-1 may have a circuit configuration in which various capacitors or transistors are added to the above-described circuit having two transistors and one capacitor, or may have a circuit configuration different from the above-described circuit configuration having two transistors and one capacitor.

Each signal line DTL is connected to an output end of the later-described horizontal selector 31, as well as the source or drain of the write transistor Tr2. Each scan line WSL is connected to an output end of the later-described write scanner 32 and the gate of the write transistor Tr2. Each power supply line DSL is connected to a power supply circuit and the source or drain of the drive transistor Tr1.

The gate of the write transistor Tr2 is connected to the scan line WSL. The source or the drain of the write transistor Tr2 is connected to the signal line DTL. The terminal from among the source and drain of the write transistor Tr2 that is not connected to the signal line DTL is connected to the gate of the drive transistor Tr1. The source or the drain of the drive transistor Tr1 is connected to the power supply line DSL. The terminal from among the source and drain of the drive transistor Tr1 that is not connected to the power supply line DSL is connected to a positive electrode 21 of the organic electroluminescent section 18-2. One end of the storage capacitor Cs is connected to the gate of the drive transistor Tr1. The other end of the storage capacitor Cs is connected to, from among the source and drain of the drive transistor Tr1, the terminal on the organic electroluminescent section 18-2 side.

### Driver 30

The driver 30 has a horizontal selector 31 and a write scanner 32, for example. For example, the horizontal selector 31, in response to (in synchronization with) input of a control signal, applies an analog signal voltage Vsig inputted from the controller 20, to each signal line DTL. The write scanner 32 scans the plurality of pixels 18 in each predetermined unit.

### Controller 20

Next, description is given regarding the controller 20. The controller 20, for example, performs a predetermined correction on the digital image signal Din inputted from an outside unit, and generates the signal voltage Vsig on the basis of an image signal obtained as a result. For example, the controller 20 outputs the generated signal voltage Vsig to the horizontal selector 31. For example, the controller 20 outputs a control signal to each circuit inside the driver 30 in response to (in synchronization with) the synchronization signal Tin that is inputted from an outside unit.

In the present application example, the light-emitting apparatus 1 is used as a display panel for displaying an image. As a result, even in a case where the light-emitting apparatus 1 is large, it is possible to provide a display apparatus 2 that is superior in display quality and has low angle dependence for chromaticity and luminance.

### Application Example B

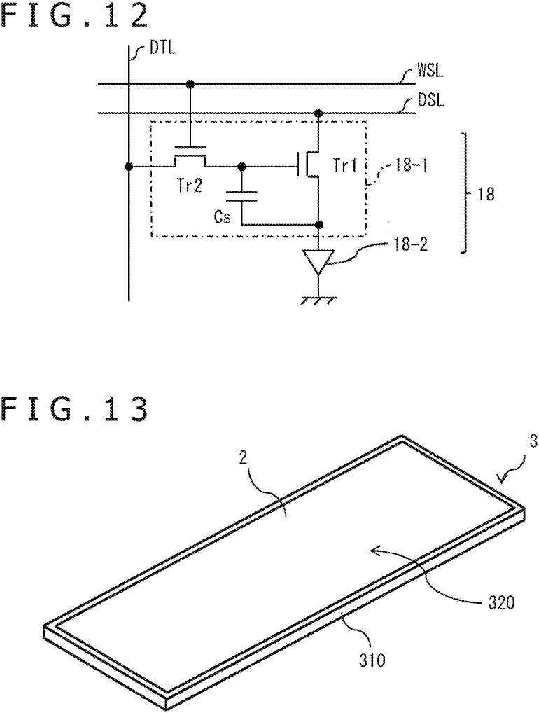

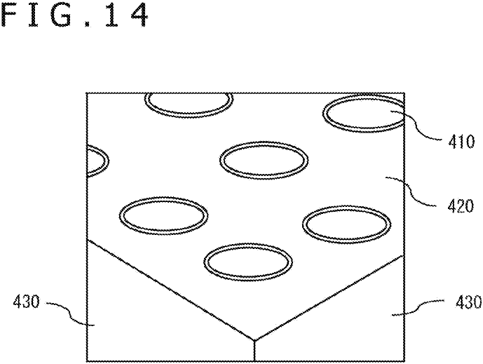

The display apparatus 2 according to the application example A described above can be used in electronic equipment of various types. FIG. 13 represents a perspective configuration of electronic equipment 3 to which the display apparatus 2 according to the application example A described above has been applied. The electronic equipment 3 is, for example, a personal computer that has a sheet shape and is provided with a display surface 320 on the main surface of a case 310. The electronic equipment 3 is provided with the display apparatus 2 according to the application example A described above, on a display surface 320 of the electronic equipment 3. The display apparatus 2 according to the application example A described above is disposed so that an image display surface faces outside. In the present application example, because the display apparatus 2 according to the application example A described above is provided on the display surface 320, even in a case where the display surface 320 is large, it is possible to provide the electronic equipment 3 that is superior in display quality and has low angle dependence for chromaticity and luminance.

### Application Example C

Description is given below regarding an application example for the light-emitting apparatus 1 according to the above-described embodiment and variations thereof. The light-emitting apparatus 1 according to the above-described embodiment and variations thereof can be applied to a light source for an illumination apparatus in various fields, such as a desktop or floor illumination apparatus or an indoor illumination apparatus.

FIG. 14 represents the appearance of an indoor illumination apparatus to which the light-emitting apparatus 1 according to the above-described embodiment and variations thereof is applied. For example, this illumination apparatus has an illumination unit 410 that is configured by including the light-emitting apparatus 1 according to the above-described embodiment and variations thereof. An appropriate number of the illumination units 410 are disposed at appropriate intervals on a ceiling 420 of a building. Note that, in accordance with an intended use, the illumination unit 410 is not limited to the ceiling 420 and can be installed at any location such as a wall 430 or a floor (not illustrated).

In these illumination apparatuses, illumination is performed using light from the light-emitting apparatus 1 according to the above-described embodiment and variations thereof. As a result, it is possible to realize an illumination apparatus that has high illumination quality and has low angle dependence for chromaticity and luminance.

The present disclosure has been described above by giving an embodiment, but the present disclosure is not limited to the embodiment, and various modifications are possible. Note that effects described in the present specification are purely examples. Effects according to the embodiment of the present disclosure are not limited to effects described in the present specification. The present disclosure may have effects other than those described in the present specification.

In addition, the present disclosure can also have configurations such as the following.
(1) A light-emitting apparatus including:
   a plurality of organic electroluminescent sections that each include a first reflective layer, an organic light-emitting layer, and a second reflective layer, in this order;
   a light extraction surface from which light emitted from each of the organic electroluminescent sections via the second reflective layer is extracted; and
   a laminate section that includes a plurality of types of transparent material layers different from a metal reflective film and is provided between each of the organic electroluminescent sections and the light extraction surface, in which
   the second reflective layer includes, from the organic light-emitting layer side, a first metal layer, a transparent layer, and a second metal layer thinner than the first metal layer, in this order, and,
   in each of the organic electroluminescent sections, an interference structure is formed according to a structure that includes a reflection interface A on the organic light-emitting layer side of the first reflective layer, a reflection interface B on the organic light-emitting layer side of the first metal layer, a reflection interface C on the light extraction surface side of the first metal layer, a reflection interface D on the organic light-emitting layer side of the second metal layer, and one or more reflection interfaces E formed according to differences in refractive indexes within the laminate section.
(2) A light-emitting apparatus including:
   a plurality of organic electroluminescent sections that each include a first reflective layer, an organic light-emitting layer, and a second reflective layer, in this order; and
   a light extraction surface from which light emitted from each of the organic electroluminescent sections via the second reflective layer is extracted, in which
   the second reflective layer includes, from the organic light-emitting layer side, a first metal layer, a first transparent layer, a second metal layer thinner than the first metal layer, a second transparent layer, and a third metal layer thinner than the first metal layer, in this order, and
   in each of the organic electroluminescent sections, an interference structure is formed according to a structure that includes a reflection interface A on the organic light-emitting layer side of the first reflective layer, a reflection interface B on the organic light-emitting layer side of the first metal layer, a reflection interface C on the light extraction surface side of the first metal layer, a reflection interface D on the organic light-emitting layer side of the second metal layer, and a reflection interface E on the organic light-emitting layer side of the third metal layer.
(3) The light-emitting apparatus according to (1) or (2), in which
   an optical distance between the reflection interface B and the reflection interface D is less than or equal to a central wavelength of light emitted from the corresponding organic light-emitting layer.
(4) The light-emitting apparatus according to one of (1) through (3), in which
the plurality of organic electroluminescent sections include a plurality of first organic electroluminescent sections and a plurality of second organic electroluminescent sections, and,
in each of the first organic electroluminescent sections and each of the second organic electroluminescent sections, the interference structure is configured to satisfy the following formulae (a) through (j):
$$2 \text{La1} / \text{λ} \text{a1} + \text{φ} \text{a1} / \left(2 π\right) = \text{Na}$$
$$\text{λ} \text{a} - 150 < \text{λ} \text{a1} < \text{λ} \text{a} + 80$$
$$2 \text{La2} / \text{λ} \text{a2} + \text{φ} \text{a2} / \left(2 π\right) = \text{Ma}$$
$$\text{λ} \text{a} - 80 < \text{λ} \text{a2} < \text{λ} \text{a} + 80$$
$$2 \text{La} {\text{2}}^{′} / \text{λ} \text{a} {\text{2}}^{′} + \text{φ} \text{a} {\text{2}}^{′} / \left(2 π\right) = \text{Ma} + 1 / 2$$
$$\text{λ} \text{a} - 80 < \text{λ} \text{a} {\text{2}}^{′} < \text{λ} \text{a} + 80$$
$$2 \text{La3} / \text{λ} \text{a3} + \text{φ} \text{a3} / \left(2 π\right) = \text{Ka} + 1 / 2$$
$$\text{λ} \text{a} - 150 < \text{λ} \text{a3} < \text{λ} \text{a} + 150$$
$$2 \text{La4} / \text{λ} \text{a4} + \text{φ} \text{a4} / \left(2 π\right) = \text{Kd} + 1 / 2$$
$$\text{λ} \text{a} - 150 < \text{λ} \text{a4} < \text{λ} \text{a} + 150$$
La1: an optical distance between the reflection interface A and a light emission center of the organic light-emitting layer in the first organic electroluminescent section,
La2: an optical distance between the reflection interface B and the light emission center of the organic light-emitting layer in the first organic electroluminescent section,
La2′: an optical distance between the reflection interface C and the light emission center of the organic light-emitting layer in the first organic electroluminescent section,
La3: an optical distance between the reflection interface D and the light emission center of the organic light-emitting layer in the first organic electroluminescent section,
La4: an optical distance between the reflection interface E and the light emission center of the organic light-emitting layer in the first organic electroluminescent section,
φa1: a phase change when light emitted from the organic light-emitting layer is reflected by the reflection interface A in the first organic electroluminescent section,
φa2: a phase change when light emitted from the organic light-emitting layer is reflected by the reflection interface B in the first organic electroluminescent section,
φa2′: a phase change when light emitted from the organic light-emitting layer is reflected by the reflection interface C in the first organic electroluminescent section,
φa3: a phase change when light emitted from the organic light-emitting layer is reflected by the reflection interface D in the first organic electroluminescent section,
φa4: a phase change when light emitted from the organic light-emitting layer is reflected by the reflection interface E in the first organic electroluminescent section,
λa: a central wavelength of an emission spectrum for the organic light-emitting layer in the first organic electroluminescent section,
$$\text{λ} \text{a1} : \text{a wavelength that satisfies formula}$$
$$\text{λ} \text{a2} : \text{a wavelength that satisfies formula}$$
$$\text{λ} \text{a} {\text{2}}^{′} : \text{a wavelength that satisfies formula}$$
$$\text{λ} \text{a3} : \text{a wavelength that satisfies formula}$$
$$\text{λ} \text{a4} : \text{a wavelength that satisfies formula}$$
and
Na, Ma, Ka, and Kd: integers that are greater than or equal to 0.
(5) The light-emitting apparatus according to (4), in which,
in each of the first organic electroluminescent sections and each of the second organic electroluminescent sections,
the microcavity structure is configured to satisfy the following formulae (k) through (t):
$$2 \text{Lc1} / \text{λ} \text{c1} + \text{φ} \text{c1} / \left(2 π\right) = \text{Nc}$$
$$\text{λ} \text{c} - 150 < \text{λ} \text{c1} < \text{λ} \text{c} + 80$$
$$2 \text{Lc2} / \text{λ} \text{c2} + \text{φ} \text{c2} / \left(2 π\right) = \text{Mc}$$
$$\text{λ} \text{c} - 80 < \text{λ} \text{c} {\text{2}}^{′} < \text{λ} \text{c} + 80$$
$$2 \text{Lc} {\text{2}}^{′} / \text{λ} \text{c} {\text{2}}^{′} + \text{φ} \text{c} {\text{2}}^{′} / \left(2 π\right) = \text{Mc} + 1 / 2$$
$$\text{λ} \text{c} - 80 < \text{λ} \text{c} {\text{2}}^{′} < \text{λ} \text{c} + 80$$
$$2 \text{Lc3} / \text{λ} \text{c3} + \text{φ} \text{c3} / \left(2 π\right) = \text{Kc}$$
$$\text{λ} \text{c} - 150 < \text{λ} \text{c3} < \text{λ} \text{c} + 150$$
$$2 \text{Lc4} / \text{λ} \text{c4} + \text{φ} \text{c4} / \left(2 π\right) = \text{Kf}$$
$$\text{λ} \text{c} - 150 < \text{λ} \text{c4} < \text{λ} \text{c} + 150$$
Lc1: an optical distance between the reflection interface A and a light emission center of the organic light-emitting layer in the second organic electroluminescent section,
Lc2: an optical distance between the reflection interface B and the light emission center of the organic light-emitting layer in the second organic electroluminescent section,
Lc2′: an optical distance between the reflection interface C and the light emission center of the organic light-emitting layer in the second organic electroluminescent section,
Lc3: an optical distance between the reflection interface D and the light emission center of the organic light-emitting layer in the second organic electroluminescent section,
Lc4: an optical distance between the reflection interface E and the light emission center of the organic light-emitting layer in the second organic electroluminescent section,
φc1: a phase change when light emitted from the organic light-emitting layer is reflected by the reflection interface A in the second organic electroluminescent section,
φc2: a phase change when light emitted from the organic light-emitting layer is reflected by the reflection interface B in the second organic electroluminescent section,
φc2′: a phase change when light emitted from the organic light-emitting layer is reflected by the reflection interface C in the second organic electroluminescent section,
φc3: a phase change when light emitted from the organic light-emitting layer is reflected by the reflection interface D in the second organic electroluminescent section,
φc4: a phase change when light emitted from the organic light-emitting layer is reflected by the reflection interface E in the second organic electroluminescent section,
λc: a central wavelength of emission spectrum for the organic light-emitting layer in the second organic electroluminescent section,
$$\text{λ} \text{c1} : \text{a wavelength that satisfies formula}$$
$$\text{λ} \text{c2} : \text{a wavelength that satisfies formula}$$
$$\text{λ} \text{c} {\text{2}}^{′} : \text{a wavelength that satisfies formula}$$
$$\text{λ} \text{c3: a wavelength thats satisfies formula}$$
$$\text{λ} \text{c4: a wavelength thats satisfies formula}$$
and
Nc, Mc, Kc, and Kf: integers that are greater than or equal to 0.
(6) The light-emitting apparatus according to one of (1) through (5), in which
   the plurality of organic electroluminescent sections include a plurality of first organic electroluminescent sections that emit light in a first wavelength band and a plurality of second organic electroluminescent sections that emit light in a second wavelength band having shorter wavelengths than the first wavelength band, and
   in each first organic electroluminescent section and each second organic electroluminescent section, the interference structure is configured such that the reflection interface A and the reflection interface B strengthen light in each of the first wavelength band and the second wavelength band, is configured such that the reflection interface C weakens light in each of the first wavelength band and the second wavelength band, and is configured such that the reflection interface D and the reflection interface E weaken light in the first wavelength band and strengthen light in the second wavelength band.
(7) The light-emitting apparatus according to one of (1) through (6), in which
   a total thickness of the first metal layer and the second metal layer is less than or equal to 44 nm.
(8) The light-emitting apparatus according to (1), in which
   the transparent layer is formed using a transparent electrical conductor material, and
   the first metal layer, the transparent layer, and the second metal layer are electrically connected to each other, and function as an electrode on the light extraction surface side.
(9) The light-emitting apparatus according to (2), in which
   the first transparent layer and the second transparent layer are formed using a transparent electrical conductor material, and
   the first metal layer, the first transparent layer, the second metal layer, the second transparent layer, and the third metal layer are electrically connected to each other and function as an electrode on the light extraction surface side.
(10) The light-emitting apparatus according to one of (1) through (9), in which
   the organic light-emitting layer is a printed layer.

The present disclosure contains subject matter related to that disclosed in Japanese Patent Application No. 2021-211958 filed in the Japan Patent Office on Dec. 27, 2021, the entire content of which is hereby incorporated by reference.

What is claimed is:

1. A light-emitting apparatus comprising:
a plurality of organic electroluminescent sections that each include a first reflective layer, an organic light-emitting layer, and a second reflective layer, in this order;
a light extraction surface from which light emitted from each of the organic electroluminescent sections via the second reflective layer is extracted; and
a laminate section that includes a plurality of types of transparent material layers different from a metal reflective film and is provided between each of the organic electroluminescent sections and the light extraction surface, wherein
the second reflective layer includes, from the organic light-emitting layer side, a first metal layer, a transparent layer, and a second metal layer thinner than the first metal layer, in this order, and,
in each of the organic electroluminescent sections, an interference structure is formed according to a structure that includes a reflection interface A on the organic light-emitting layer side of the first reflective layer, a reflection interface B on the organic light-emitting layer side of the first metal layer, a reflection interface C on the light extraction surface side of the first metal layer, a reflection interface D on the organic light-emitting layer side of the second metal layer, and one or more reflection interfaces E formed according to differences in refractive indexes within the laminate section.

2. A light-emitting apparatus comprising:
a plurality of organic electroluminescent sections that each include a first reflective layer, an organic light-emitting layer, and a second reflective layer, in this order; and
a light extraction surface from which light emitted from each of the organic electroluminescent sections via the second reflective layer is extracted, wherein
the second reflective layer includes, from the organic light-emitting layer side, a first metal layer, a first transparent layer, a second metal layer thinner than the first metal layer, a second transparent layer, and a third metal layer thinner than the first metal layer, in this order, and
in each of the organic electroluminescent sections, an interference structure is formed according to a structure that includes a reflection interface A on the organic light-emitting layer side of the first reflective layer, a reflection interface B on the organic light-emitting layer side of the first metal layer, a reflection interface C on the light extraction surface side of the first metal layer, a reflection interface D on the organic light-emitting layer side of the second metal layer, and a reflection interface E on the organic light-emitting layer side of the third metal layer.

3. The light-emitting apparatus according to claim 1, wherein
an optical distance between the reflection interface B and the reflection interface D is less than or equal to a central wavelength of light emitted from the corresponding organic light-emitting layer.

4. The light-emitting apparatus according to claim 1, wherein
the plurality of organic electroluminescent sections include a plurality of first organic electroluminescent sections and a plurality of second organic electroluminescent sections, and,
in each of the first organic electroluminescent sections and each of the second organic electroluminescent sections, the interference structure is configured to satisfy the following formulae (a) through (j):
$$\text{2La1} / \text{λ} \text{a1} + \text{φ} \text{a1} / \left(2 π\right) = \text{Na}$$
$$\text{λ} \text{a} - 150 < \text{λ} \text{a1} < \text{λ} \text{a} + 80$$
$$2 \text{La2} / \text{λ} \text{a2} + \text{φ} \text{a2} / \left(2 π\right) = \text{Ma}$$
$$\text{λ} \text{a} - 80 < \text{λ} \text{a2} < \text{λ} \text{a} + 80$$
$$2 \text{La} {\text{2}}^{′} / \text{λ} \text{a} {\text{2}}^{′} + \text{φ} \text{a} {\text{2}}^{′} / \left(2 π\right) = \text{Ma} + 1 / 2$$
$$\text{λ} \text{a} - 80 < \text{λ} \text{a} {\text{2}}^{′} < \text{λ} \text{a} + 80$$
$$2 \text{La3} / \text{λ} \text{a3} + \text{φ} \text{a3} / \left(2 π\right) = \text{Ka} + 1 / 2$$
$$\text{λ} \text{a} - 150 < \text{λ} \text{a3} < \text{λ} \text{a} + 150$$
$$2 \text{La4} / \text{λ} \text{a4} + \text{φ} \text{a4} / \left(2 π\right) = \text{Kd} + 1 / 2$$
$$\text{λ} \text{a} - 150 < \text{λ} \text{a4} < \text{λ} \text{a} + 150$$
La1: an optical distance between the reflection interface A and a light emission center of the organic light-emitting layer in the first organic electroluminescent section,
La2: an optical distance between the reflection interface B and the light emission center of the organic light-emitting layer in the first organic electroluminescent section,
La2′: an optical distance between the reflection interface C and the light emission center of the organic light-emitting layer in the first organic electroluminescent section,
La3: an optical distance between the reflection interface D and the light emission center of the organic light-emitting layer in the first organic electroluminescent section,
La4: an optical distance between the reflection interface E and the light emission center of the organic light-emitting layer in the first organic electroluminescent section,
φa1: a phase change when light emitted from the organic light-emitting layer is reflected by the reflection interface A in the first organic electroluminescent section,
φa2: a phase change when light emitted from the organic light-emitting layer is reflected by the reflection interface B in the first organic electroluminescent section, φa2′: a phase change when light emitted from the organic light-emitting layer is reflected by the reflection interface C in the first organic electroluminescent section,
φa3: a phase change when light emitted from the organic light-emitting layer is reflected by the reflection interface D in the first organic electroluminescent section,
φa4: a phase change when light emitted from the organic light-emitting layer is reflected by the reflection interface E in the first organic electroluminescent section,
λa: a central wavelength of an emission spectrum for the organic light-emitting layer in the first organic electroluminescent section,
λa1: a wavelength that satisfies formula (b),
λa2: a wavelength that satisfies formula (d),
λa2′ : a wavelength that satisfies formula (f),
λa3: a wavelength that satisfies formula (h),
λa4: a wavelength that satisfies formula (j), and
Na, Ma, Ka, and Kd: integers that are greater than or equal to 0.

5. The light-emitting apparatus according to claim 4, wherein,
in each of the first organic electroluminescent sections and each of the second organic electroluminescent sections, the microcavity structure is configured to satisfy the following formulae (k) through (t):
$$2 \text{Lc1} / \text{λ} \text{c1} + \text{φ} \text{c1} / \left(2 π\right) = \text{Nc}$$
$$\text{λ} \text{c} - 150 < \text{λ} \text{c1} < \text{λ} \text{c} + 80$$
$$2 \text{Lc2} / \text{λ} \text{c2} + \text{φ} \text{c2} / \left(2 π\right) = \text{Mc}$$
$$\text{λ} \text{c} - 80 < \text{λ} \text{c} {\text{2}}^{′} < \text{λ} \text{c} + 80$$
$$2 \text{Lc} {\text{2}}^{′} / \text{λ} \text{c} {\text{2}}^{′} + \text{φ} \text{c} {\text{2}}^{′} / \left(2 π\right) = \text{Mc} + 1 / 2$$
$$\text{λ} \text{c} - 80 < \text{λ} \text{c} {\text{2}}^{′} < \text{λ} \text{c} + 80$$
$$2 \text{Lc3} / \text{λ} \text{c3} + \text{φ} \text{c3} / \left(2 π\right) = \text{Kc}$$
$$\text{λ} \text{c} - 150 < \text{λ} \text{c3} < \text{λ} \text{c} + 150$$
$$2 \text{Lc4} / \text{λ} \text{c4} + \text{φ} \text{c4} / \left(2 π\right) = \text{Kf}$$
$$\text{λ} \text{c} - 150 < \text{λ} \text{c4} < \text{λ} \text{c} + 150$$
Lc1: an optical distance between the reflection interface A and a light emission center of the organic light-emitting layer in the second organic electroluminescent section,
Lc2: an optical distance between the reflection interface B and the light emission center of the organic light-emitting layer in the second organic electroluminescent section,
Lc2′: an optical distance between the reflection interface C and the light emission center of the organic light-emitting layer in the second organic electroluminescent section,
Lc3: an optical distance between the reflection interface D and the light emission center of the organic light-emitting layer in the second organic electroluminescent section,
Lc4: an optical distance between the reflection interface E and the light emission center of the organic light-emitting layer in the second organic electroluminescent section,
φc1: a phase change when light emitted from the organic light-emitting layer is reflected by the reflection interface A in the second organic electroluminescent section,
φc2: a phase change when light emitted from the organic light-emitting layer is reflected by the reflection interface B in the second organic electroluminescent section,
φc2′: a phase change when light emitted from the organic light-emitting layer is reflected by the reflection interface C in the second organic electroluminescent section,
φc3: a phase change when light emitted from the organic light-emitting layer is reflected by the reflection interface D in the second organic electroluminescent section,
φc4: a phase change when light emitted from the organic light-emitting layer is reflected by the reflection interface E in the second organic electroluminescent section,
λc: a central wavelength of an emission spectrum for the organic light-emitting layer in the second organic electroluminescent section,
λc1: a wavelength that satisfies formula (l),
λc2: a wavelength that satisfies formula (n),
λc2′: a wavelength that satisfies formula (p),
λc3: a wavelength that satisfies formula (r), λc4: a wavelength that satisfies formula (t), and
Nc, Mc, Kc, and Kf: integers that are greater than or equal to 0.

6. The light-emitting apparatus according to claim 1, wherein
the plurality of organic electroluminescent sections include a plurality of first organic electroluminescent sections that emit light in a first wavelength band and a plurality of second organic electroluminescent sections that emit light in a second wavelength band having shorter wavelengths than the first wavelength band, and
in each of the first organic electroluminescent sections and each of the second organic electroluminescent sections, the interference structure is configured such that the reflection interface A and the reflection interface B strengthen light in each of the first wavelength band and the second wavelength band, is configured such that the reflection interface C weakens light in each of the first wavelength band and the second wavelength band, and is configured such that the reflection interface D and the reflection interface E weaken light in the first wavelength band and strengthen light in the second wavelength band.

7. The light-emitting apparatus according to claim 1, wherein
a total thickness of the first metal layer and the second metal layer is less than or equal to 44 nm.

8. The light-emitting apparatus according to claim 1, wherein
the transparent layer is formed using a transparent electrical conductor material, and
the first metal layer, the transparent layer, and the second metal layer are electrically connected to each other and function as an electrode on the light extraction surface side.

9. The light-emitting apparatus according to claim 2, wherein
the first transparent layer and the second transparent layer are formed using a transparent electrical conductor material, and
the first metal layer, the first transparent layer, the second metal layer, the second transparent layer, and the third metal layer are electrically connected to each other and function as an electrode on the light extraction surface side.

10. The light-emitting apparatus according to claim 1, wherein
the organic light-emitting layer is a printed layer.
